(19) United States
(12) Patent Application Publication
(10) Pub. No.: US 2007/0148493 A1
(43) Pub. Date: Jun. 28, 2007

(54) Organic electroluminescence device

(75) Inventors: Hirohito Yoneyama, Kanagawa (JP); Yohei Nishino, Kanagawa (JP); Mieko Seki, Kanagawa (JP); Daisuke Okuda, Kanagawa (JP); Hidekazu Hirose, Kanagawa (JP); Tadayoshi Ozaki, Kanagawa (JP); Takeshi Agata, Kanagawa (JP); Toru Ishii, Kanagawa (JP); Kiyokazu Mashimo, Kanagawa (JP); Katsuhiro Sato, Kanagawa (JP); Koji Horiba, Kanagawa (JP); Akira Imai, Kanagawa (JP)

Correspondence Address: FILDES & OUTLAND, P.C., 20916 MACK AVENUE, SUITE 2, GROSSE POINTE WOODS, MI, 48236, US

(73) Assignee: Fuji Xerox Co., Ltd.

(21) Appl. No.: 11/633,985

(22) Filed: Dec. 5, 2006

(30) Foreign Application Priority Data
Dec. 26, 2005 (JP) 2005-373349
Aug. 15, 2006 (JP) 2006-221507

(51) Int. Cl. H01L 51/54

(52) U.S. Cl. 428/690; 428/917; 313/504; 313/506; 257/40; 257/E51.026

(57) ABSTRACT

The invention provides an organic electroluminescence device having a pair of electrodes at least one of which is transparent or translucent and plural organic compound layers positioned between the pair of electrodes, at least one of the plural organic compound layers being a hole transport layer in which an electron transport material is mixed with at least one hole transport polymer, and at least one of the plural organic compound layers containing a luminescent material.

### BACKGROUND

1. Technical Field

The present invention relates to an organic electroluminescence device, and more particularly to an organic electroluminescence device using a specific hole transport polymer.

2. Related Art

Electroluminescence devices (hereinafter, referred to as “EL device” in some cases) are self-luminescent solid-state devices having high visibility and high impact resistance, and are expected to be applied widely. Conventionally, inorganic phosphors are mainly used as EL devices, and EL devices in which a rare earth device such as Eu, Ce, Tb, or Sn, or Mn serving as a luminescent center is doped in a Group II-VI compound semiconductor, which is an inorganic material, such as ZnS, CaS, or SrS are generally used. However, driving EL devices made of such an inorganic material requires a high alternating current voltage of over 200 V, manufacturing costs are high, it is hard for the EL devices to realize full-color display, and luminance is insufficient.

Recently, Tang et al. has proposed a new EL device that is obtained by vacuum-depositing and laminating two very thin layers between an anode and a cathode, and that has realized high luminance at a low driving voltage. Laminated organic EL devices like this are being intensively studied. Further, an EL device having three layers to which charge transport and luminescence functions are allocated has been reported. The appearance of such EL devices alleviates restrictions on charge transport performance, increases the latitude of selection of a pigment to be contained in a luminescent layer on which pigment the color of light emission depends, and suggests a possibility of effectively confining holes and electrons (or exciters) in a luminescent layer disposed centrally to improve luminescence.

As a result of such research and development of organic EL devices, it is now possible to emit light at a low direct current voltage of about several volts to several tens of volts. Further, by selecting the type of a fluorescent organic compound, light of various colors (such as red, blue, and green) can be emitted.

To address various problems related to the thermal stability of EL devices, use of a starburst amine that may be obtained in a stable amorphous glass state as a hole transport material has been reported. Also, use of a polymer having triethanolamine in the side chains of polyphosphazen has been reported.

On the other hand, a single-layered EL device has been also studied and developed, and a device using a conductive polymer such as poly(p-phenylenevinylene) has been reported. Further, a device including hole transport polyvinyl carbazole with which an electron transport material and a fluorescent pigment are mixed has been proposed.

These organic EL devices having such features are expected to be applied in various light emitting devices and display devices.

One of the major issues in the application of organic EL devices in the field of flat panel displays is to lengthen the life of the devices. The limit of the life of devices appears in the form of a spreading non-luminescent area (dark spot) in the course of emitting light for a long time, and one of the factors is deterioration in the organic EL layers of the organic EL devices, which is a serious problem.

### SUMMARY

According to an aspect of the invention, there is provided an organic electroluminescence device having a pair of electrodes at least one of which is transparent or translucent, and plural organic compound layers positioned between the pair of electrodes, at least one of the plural organic compound layers being a hole transport layer in which an electron transport material is mixed with at least one hole transport material, and at least one of the plural organic compound layers containing a luminescent material.

### BRIEF DESCRIPTION OF THE DRAWINGS

Exemplary embodiments of the invention will be described in detail based on the following figures, wherein:

FIG. 1 is a schematic sectional view showing an example of the layer configuration of an organic electroluminescence device of the invention;

FIG. 2 is a schematic sectional view showing another example of the layer configuration of the organic electroluminescence device of the invention; and

FIG. 3 is a schematic sectional view showing other example of the layer configuration of the organic electroluminescence device of the invention.

### DETAILED DESCRIPTION

An electroluminescence device (hereinafter may be called an organic EL device) of the invention will be described.

The organic electroluminescence device of an aspect of the invention has a pair of electrodes at least one of which is transparent or translucent and plural organic compound layers positioned between the pair of electrodes, and at least one of the plural organic compound layers is a hole transport layer in which at least one electron transport material is mixed with at least one hole transport material, and at least one of the plural organic compound layers contains at least one luminescent material.

In the organic electroluminescence device of the aspect having plural organic compound layers, holes injected from the anode are transported to the luminescent layer by the hole transport layer, and, in the luminescent layer bulk or at the interface between the hole transport layer and the luminescent layer, are recombined with electrons injected from the cathode and transported to the luminescent layer. The organic electroluminescence device emits light by the recombination.

However, a part of the electrons not recombined with the holes and not contributing to emission of light are undesirably injected into the hole transport layer. The hole transport layer is mainly composed of a hole transport material, and is a layer for transporting holes, and is excellent in the function of transporting holes, but is poor in an electron transport ability. Accordingly, the electrons not contributing to emission of light and injected into the hole transport layer remain in the hole transport layer, which is one of reasons for lowering the internal electric field, and deteriorating the hole transport material itself.

When the electrons not contributing to emission of light and remaining in the hole transport layer are accumulated in the hole transport layer, the life of the device may shorten.

Since the electron transport material is mixed with the hole transport material in the hole transport layer of the organic electroluminescence device of the aspect, the electrons not contributing to emission of light can be removed from the hole transport layer by the electron transport material, and accumulation of the electrons in the hole transport layer can be prevented. As a result, the organic electroluminescence device has a long life.

On the other hand, when an electron transport layer is included in plural organic compound layers, a part of holes not recombined with electrons and not contributing to emission of light are undesirably injected into the electron transport layer. The electron transport layer is a layer for transporting electrons, and is excellent in the function of transporting electrons, but is poor in a hole transport ability. Accordingly, the holes not contributing to emission of light remain in the electron transport layer, which is one of reasons for lowering the internal electric field, and deteriorating the electron transport material itself.

When holes not contributing to emission of light and remaining in the electron transport layer are accumulated in the electron transport layer, the life of the device may shorten.

The organic electroluminescence device of another aspect of the invention has a pair of electrodes at least one of which is transparent or translucent, and plural organic compound layers positioned between the pair of electrodes, and at least one of the plural organic compound layers is an electron transport layer in which at least one hole transport material is mixed with at least one electron transport material, and at least one of the plural organic compound layers contains at least one luminescent material.

Since the hole transport material is mixed with the electron transport material in the electron transport layer of the organic electroluminescence device of another aspect, the holes not contributing to emission of light can be removed from the electron transport layer, and accumulation of the holes in the electron transport layer can be prevented. As a result, the organic electroluminescence device has a long life.

Next, the layer configuration of the organic electroluminescence device of the invention will be explained.

The organic electroluminescence device of the invention has a pair of electrodes at least one of which is transparent or translucent, and plural organic compound layers positioned between the pair of electrodes.

In the organic electroluminescence device of the invention, at least one of the plural organic compound layers is a luminescent layer, and the other of the organic compound layers is a hole transport layer, or an electron transport layer, or are a hole transport layer and an electron transport layer.

Specifically, the organic electroluminescence device of the invention has at least, for example, a luminescent layer and an electron transport layer, or has at least a hole transport layer, a luminescent layer, and an electron transport layer, or has at least a hole transport layer and a luminescent layer. The hole transport layer is formed by mixing at least one electron transport material with at least one hole transport material, and the electron transport layer is formed by mixing at least one hole transport material with at least one electron transport material.

The organic electroluminescence device of the invention may have the hole transport layer including an electron transport material and the electron transport layer including a hole transport material, or either of the hole transport layer including an electron transport material and the electron transport layer including a hole transport material.

While the drawings are referred, the layer configuration of the organic electroluminescence device of the invention will be explained, but the invention is not limited by the drawings.

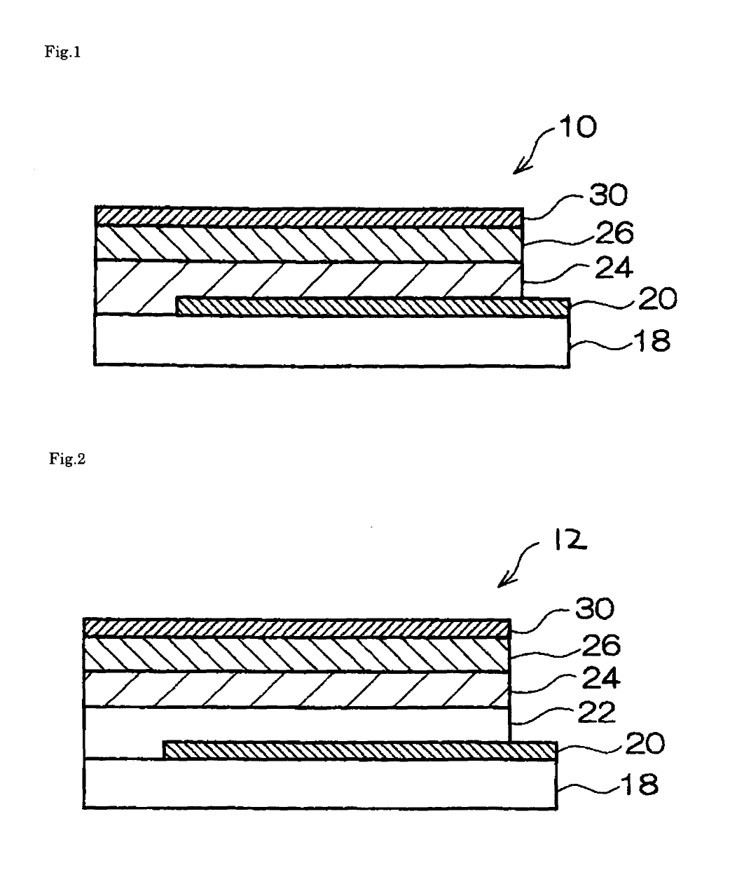

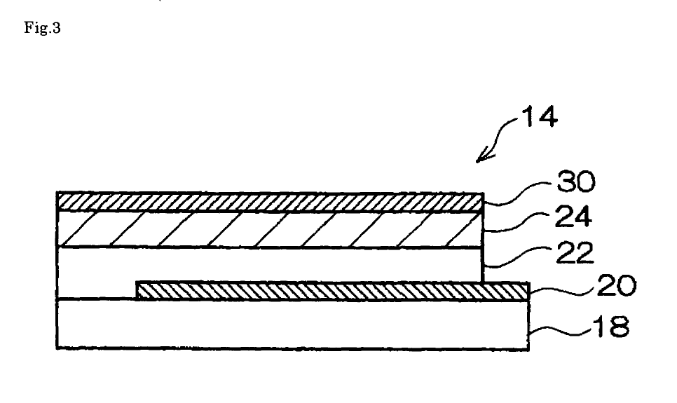

FIG. 1 to FIG. 3 are schematic sectional views each showing the layer configuration of the organic electroluminescence device of the invention, and FIG. 1, FIG. 2, and FIG. 3 show examples of organic electroluminescence device having plural organic compound layers. In FIG. 1 to FIG. 3, layers having the same function are identified with the same reference numerals.

An organic electroluminescence device 10 shown in FIG. 1 is formed by sequentially laminating a transparent insulating substrate 18, a transparent electrode 20, a luminescent layer 24, an electron transport layer 26, and a back electrode 30.

An organic electroluminescence device 12 shown in FIG. 2 is formed by sequentially laminating a transparent insulating substrate 18, a transparent electrode 20, a hole transport layer 22, a luminescent layer 24, an electron transport layer 26, and a back electrode 30.

An organic electroluminescence device 14 shown in FIG. 3 is formed by sequentially laminating a transparent insulating substrate 18, a transparent electrode 20, a hole transport layer 22, a luminescent layer 24, and a back electrode 30.

The hole transport layer in the invention in which an electron transport material is mixed with at least one hole transport polymer corresponds to the hole transport layer 22 in FIG. 2 and the hole transport layer 22 in FIG. 3.

The electron transport layer in the invention in which a hole transport material is mixed with at least one electron transport material corresponds to the electron transport layer 26 in FIGS. 1 and 2.

First of all, the hole transport material containable in the hole transport layer of the organic electroluminescence device of the invention, and/or in the electron transport layer, which will be specifically explained later, will be explained.

The hole transport layer of the organic electroluminescence device of the invention has a function of receiving holes from the anode or the anode side thereof and transporting the holes to the cathode side thereof, that is, to the luminescent layer. Accordingly, the hole mobility of the hole transport material of the hole transport layer is preferably in the range of about 1×10⁻⁸ cm²/(V.s) to about 1×10⁻² cm²/(V.s), but may be out of the range.

The hole mobility is obtained by measuring a transient light current waveform with respect to the moving amount of charged carriers, and calculating the hole mobility from the applied voltage and the thickness of a sample used in the measurement at this time. This is a method for measuring the mobility of charged carriers generally known in this technical field as a so-called time-of-flight method (TOF method).

The hole transport material contained in the hole transport layer of the organic electroluminescence device of the invention can be a high molecular weight hole transport material.

The high molecular weight hole transport material is, for example, a hole transport polymer having one or more of structures represented by the following formulas (I-1) and (I-2) as a partial structure of the repeating unit thereof.

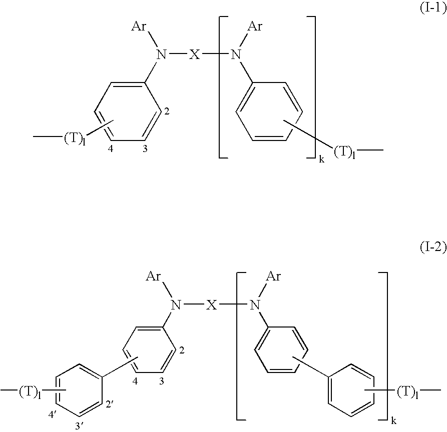

In formulas (I-1) and (I-2), Ar is a monovalent polynuclear aromatic ring having 1 to 10 substituted or unsubstituted aromatic rings, or a monovalent condensed aromatic ring having 2 to 10 substituted or unsubstituted aromatic rings, X is a substituted or unsubstituted divalent aromatic group, k and l each represent either 0 or 1, T is a linear divalent hydrocarbon group having 1 to 10 carbon atoms, or a branched divalent hydrocarbon group having 1 to 10 carbon atoms.

The polynuclear aromatic ring and the condensed aromatic ring are specifically aromatic hydrocarbons defined as follows.

The polynuclear aromatic ring is hydrocarbon having two or more aromatic rings composed of carbon and hydrogen atoms, with the aromatic rings mutually bonded via a carbon-carbon bond. Specific examples thereof include biphenyl and terphenyl. The condensed aromatic ring is hydrocarbon having two or more aromatic rings composed of carbon and hydrogen atoms, with the aromatic rings sharing a pair of carbon atoms. Specific examples thereof include naphthalene, anthracene, phenanthrene, and fluorene.

Examples of the substituent(s) of the substituted polynuclear aromatic ring or condensed aromatic ring include a hydrogen atom, alkyl groups, alkoxy groups, aryl groups, aralkyl groups, substituted amino groups, and halogen atoms.

The alkyl group preferably has 1 to 10 carbon atoms, and examples thereof include a methyl group, an ethyl group, a propyl group, and an isopropyl group. The alkoxy group preferably has 1 to 10 carbon atoms, and examples thereof include a methoxy group, an ethoxy group, a propoxy group, and an isopropoxy group.

The aryl group preferably has 6 to 20 carbon atoms, and examples thereof include a phenyl group and a tolyl group. The aralkyl group preferably has 7 to 20 carbon atoms, and examples thereof include a benzyl group and a phenethyl group.

Examples of the substituent(s) of the substituted amino group include alkyl groups, aryl groups, and aralkyl groups, and specific examples of each of these groups are described above.

Examples of the substituent(s) of the substituted aryl group and the substituted aralkyl group include a hydrogen atom, alkyl groups, alkoxy groups, substituted amino groups, and halogen atoms.

In formulas (I-1) and (I-2), X is a substituted or unsubstituted divalent aromatic group, and specific examples thereof include groups represented by the following formulas (1) to (7).

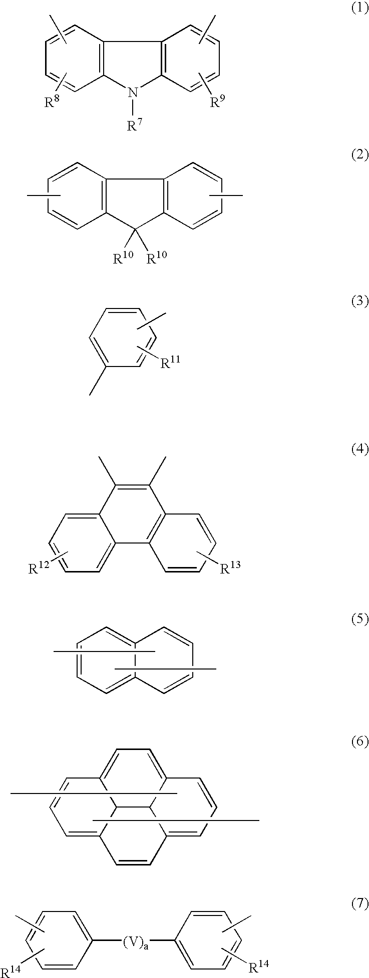

In formulas (1) to (7), R⁷ is a hydrogen atom, an alkyl group having 1 to 4 carbon atoms, a substituted or unsubstituted phenyl group, or a substituted or unsubstituted aralkyl group, and each of R⁸ to R¹⁴ represents a hydrogen atom, an alkyl group having 1 to 4 carbon atoms, an alkoxy group having 1 to 4 carbon atoms, a substituted or unsubstituted phenyl group, a substituted or unsubstituted aralkyl group, or a halogen atom, and a is 0 or 1, and V is selected from groups represented by the following formulas (8) to (17).

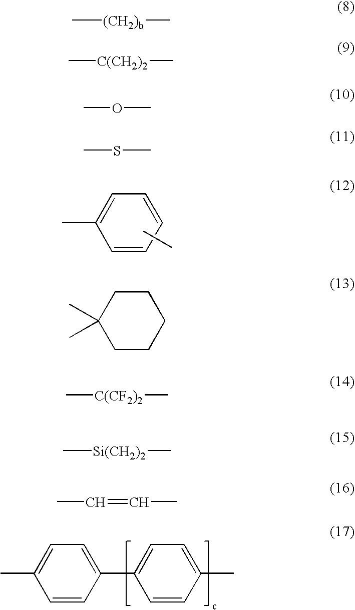

In formulas (8) to (17), b is an integer of 1 to 10, and c is an integer of 1 to 3.

In formulas (I-1) and (I-2), T is a linear divalent hydrocarbon group having 1 to 10 carbon atoms, or a branched divalent hydrocarbon group having 1 to 10 carbon atoms. When T is linear, T preferably has 1 to 6 carbon atoms, and more preferably 2 to 6 carbon atoms. When T is branched, T preferably has 2 to 10 carbon atoms, and more preferably 3 to 7 carbon atoms. Specific structural examples of T are shown below (hydrocarbon group T-1 to hydrocarbon group T-32).

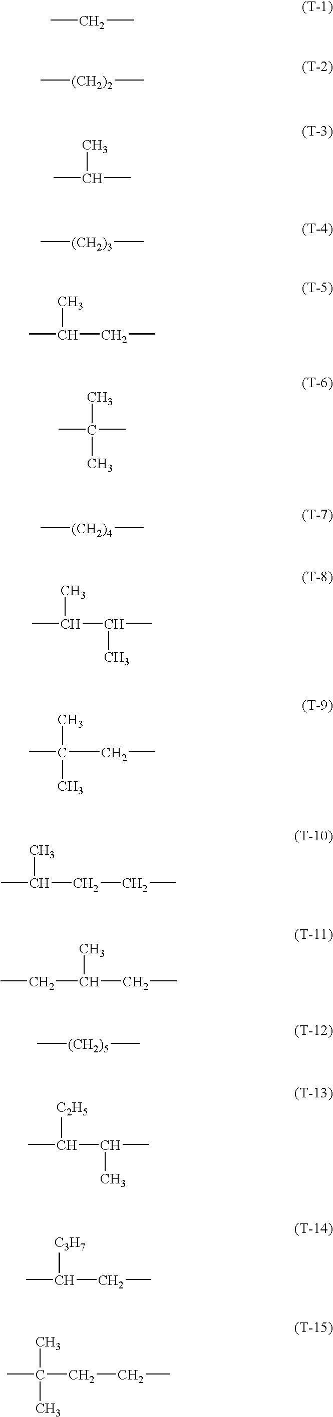

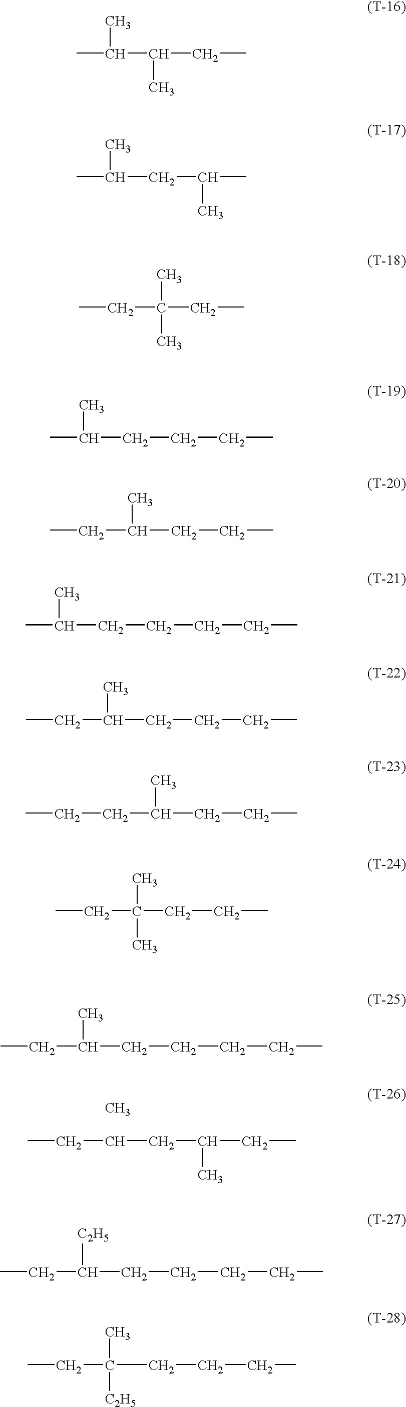

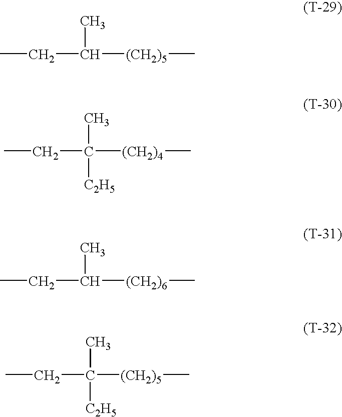

Specific examples of the partial structure represented by formula (I-1) are shown in Tables 1 to 8, and specific examples of the partial structure represented by formula (I-2) are shown in Tables 9 to 16. However, the invention is not limited by these examples.

In Tables 1 to 8, the structures shown in column X of the row of “Partial Structure” correspond to X in formula (I-1), and the structures shown in column Ar correspond to Ar in formula (I-1), and the numerals shown in column k correspond to k in formula (I-1). The marks in column T correspond to T in formula (I-1), and show the hydrocarbon groups (T-1) to (T-32).

In Tables 1 to 8, the values shown in the column of “Bonding Position” represent the numerical values indicated in one of the benzene rings in formula (I-1), and group T(s) is bonded to the benzene ring at this position. When k is 1 in the specific examples of the structure represented by formula (I-1), group (T) is bonded to the benzene ring in the brackets in the molecular structure at the same numerical position as that in the other benzene ring to which the numerical indication of the possible bond positions (2, 3, 4) is appended.

In Tables 9 to 16, the structures shown in column X of the row of “Partial Structure” correspond to X in formula (I-2), and the structures shown in column Ar correspond to Ar in formula (I-2), and the numerals shown in column k correspond to k in formula (I-2). The marks in column T correspond to T in formula (I-2), and show the hydrocarbon groups (T-1) to (T-32).

In Tables 9 to 16, the values shown in the column of “Bonding Position” represent the numerical values indicated in two of the benzene rings in formula (I-2), and group T(s) is bonded to the benzene ring at this position. When k is 1 in the specific examples of the structure represented by formula (I-2), group (T) is bonded to the benzene ring in the brackets in the molecular structure at the same numerical position as that in the benzene ring to which the numerical indication of the possible bond positions (2′, 3′, 4′) is appended, and the benzene ring in the brackets bonded to group (T) is bonded to the other benzene ring in the brackets at the same numerical position as that in the benzene ring to which the numerical indication of the possible bond positions (2, 3, 4) is appended.

TABLE 1

| Partial | | | Bonding | | |
|---|---|---|---|---|---|
| Structure | X | Ar | Position | k | T |
| 1-1 | 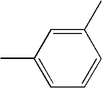 | 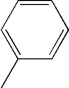 | 3 | 0 | T-2 |
| 1-2 | 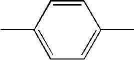 | 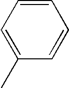 | 3 | 0 | T-2 |
| 1-3 | 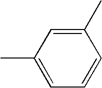 | 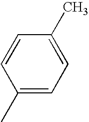 | 3 | 0 | T-2 |
| 1-4 | 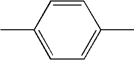 | 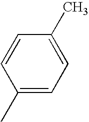 | 4 | 0 | T-2 |
| 1-5 | 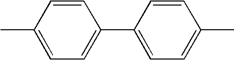 | 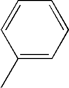 | 3 | 1 | — |
| 1-6 | 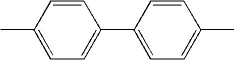 | 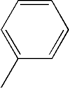 | 3 | 1 | T-2 |
| 1-7 | 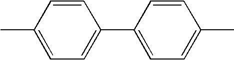 | 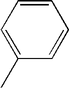 | 3 | 1 | T-5 |
| 1-8 | 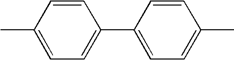 | 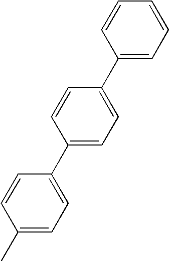 | 3 | 1 | T-2 |
| 1-9 | 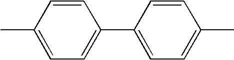 | 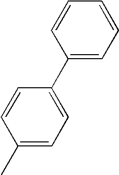 | 3 | 1 | T-2 |

TABLE 2

| Partial | | | Bonding | | |
|---|---|---|---|---|---|
| Structure | X | Ar | Position | k | T |
| 1-10 | 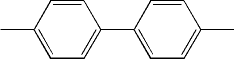 | 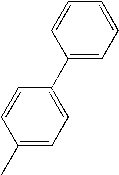 | 3 | 1 | T-8 |
| 1-11 | 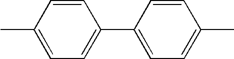 | 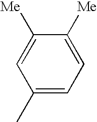 | 3 | 1 | T-25 |
| 1-12 | 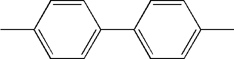 | 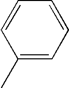 | 4 | 1 | T-5 |
| 1-13 | 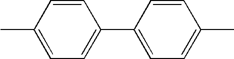 | 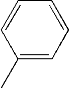 | 4 | 1 | T-1 |
| 1-14 | 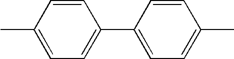 | 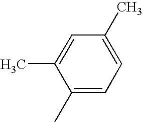 | 4 | 1 | T-2 |
| 1-15 | 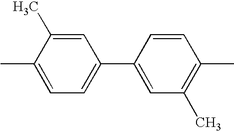 | 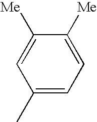 | 3 | 1 | — |
| 1-16 | 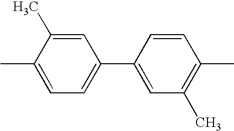 | 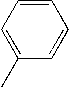 | 3 | 1 | T-2 |
| 1-17 | 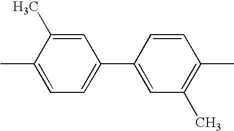 | 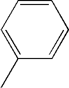 | 4 | 1 | T-2 |

TABLE 3

| Partial | | | Bonding | | |
|---|---|---|---|---|---|
| Structure | X | Ar | Position | k | T |
| 1-18 | 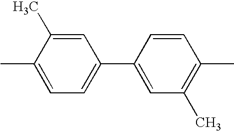 | 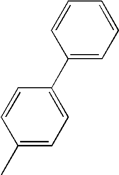 | 3 | 1 | T-1 |
| 1-19 | 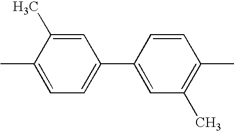 | 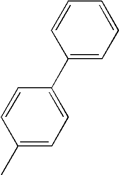 | 3 | 1 | T-2 |
| 1-20 | 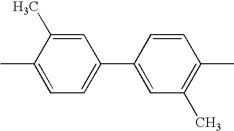 | 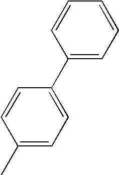 | 4 | 1 | T-4 |
| 1-21 | 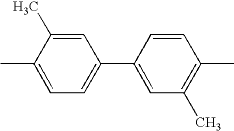 | 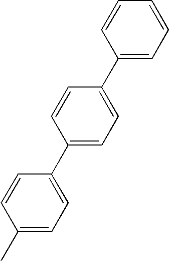 | 3 | 1 | T-2 |
| 1-22 | 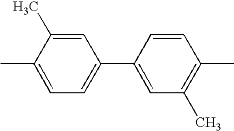 | 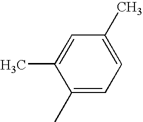 | 3 | 1 | T-2 |
| 1-23 | 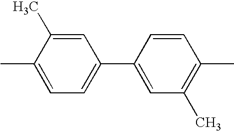 | 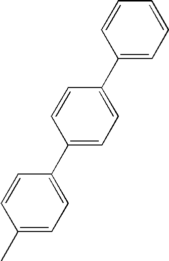 | 3 | 1 | T-13 |
| 1-24 | 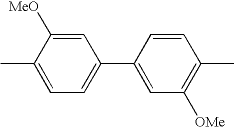 | 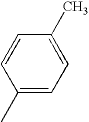 | 3 | 1 | — |
| 1-25 | 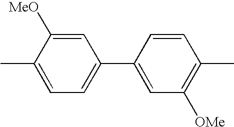 | 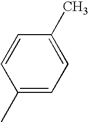 | 3 | 1 | T-2 |

TABLE 4

| Partial | | | Bonding | | |
|---|---|---|---|---|---|
| Structure | X | Ar | Position | k | T |
| 1-26 | 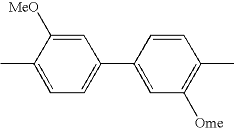 | 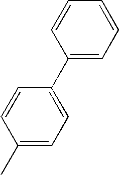 | 3 | 1 | T-2 |
| 1-27 | 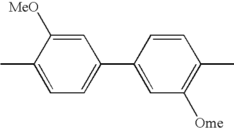 | 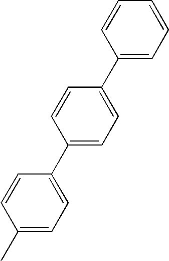 | 3 | 1 | T-2 |
| 1-28 | 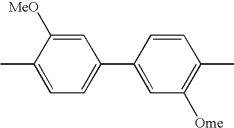 | 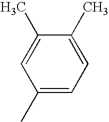 | 3 | 1 | T-8 |
| 1-29 | 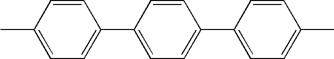 | 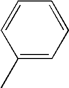 | 3 | 1 | T-2 |
| 1-30 | 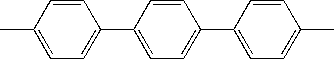 | 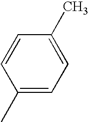 | 3 | 1 | T-2 |
| 1-31 | 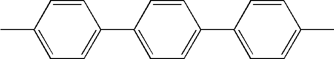 | 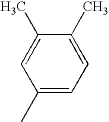 | 3 | 1 | T-2 |
| 1-32 | 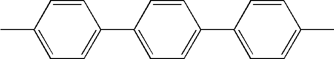 | 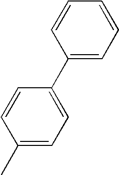 | 3 | 1 | T-2 |
| 1-33 | 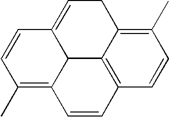 | 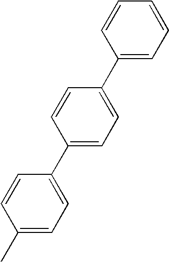 | 3 | 1 | T-2 |

TABLE 5

| Partial | | | Bonding | | |
|---|---|---|---|---|---|
| Structure | X | Ar | Position | k | T |
| 1-34 | 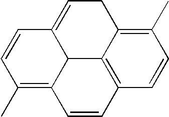 | 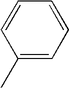 | 3 | 1 | T-8 |
| 1-35 | 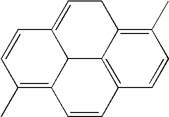 | 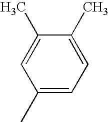 | 3 | 1 | T-18 |
| 1-36 | 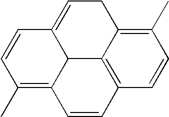 | 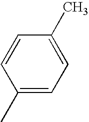 | 4 | 1 | T-20 |
| 1-37 | 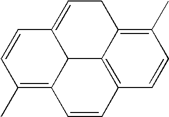 | 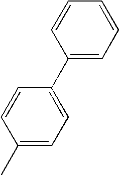 | 4 | 1 | T-24 |
| 1-38 | 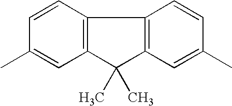 | 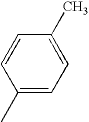 | 3 | 1 | T-2 |
| 1-39 | 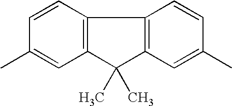 | 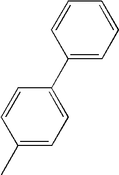 | 3 | 1 | T-8 |
| 1-40 | 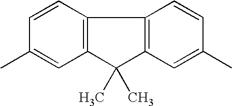 | 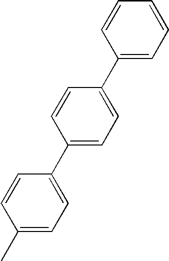 | 3 | 1 | T-18 |

TABLE 6

| Partial | | | Bonding | | |
|---|---|---|---|---|---|
| Structure | X | Ar | Position | k | T |
| 1-41 | 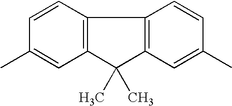 | 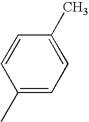 | 4 | 1 | T-20 |
| 1-42 | 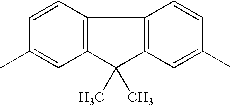 | 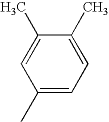 | 4 | 1 | T-24 |
| 1-43 | 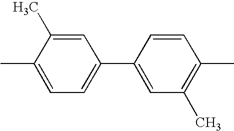 | 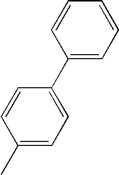 | 4 | 1 | — |
| 1-44 | 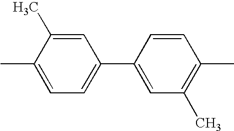 | 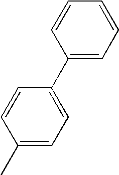 | 4 | 1 | T-1 |
| 1-45 | 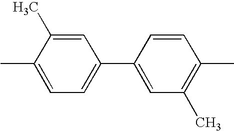 | 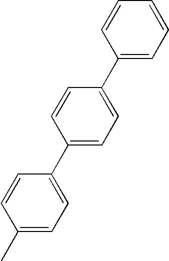 | 4 | 1 | T-2 |
| 1-46 | 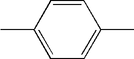 | 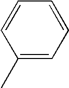 | 4 | 0 | — |
| 1-47 | 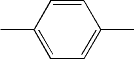 | 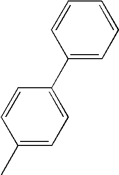 | 4 | 0 | T-1 |

TABLE 7

| Partial | | | Bonding | | |
|---|---|---|---|---|---|
| Structure | X | Ar | Position | k | T |
| 1-48 | 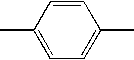 | 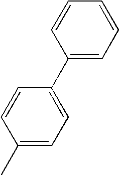 | 4 | 0 | T-2 |
| 1-49 | 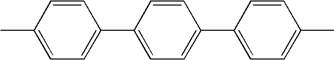 | 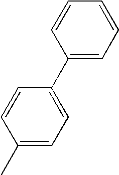 | 4 | 1 | — |
| 1-50 | 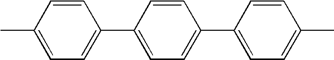 | 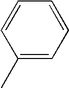 | 4 | 1 | — |
| 1-51 | 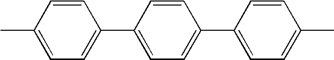 | 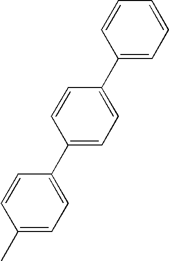 | 4 | 1 | — |
| 1-52 | 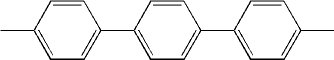 | 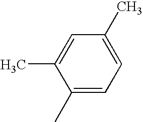 | 4 | 1 | — |
| 1-53 | 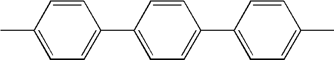 | 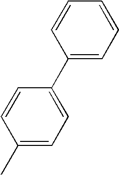 | 4 | 1 | T-2 |
| 1-54 | 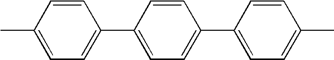 | 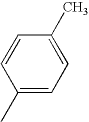 | 3 | 1 | T-18 |

TABLE 8

| Partial | | | Bonding | | |
|---|---|---|---|---|---|
| Structure | X | Ar | Position | k | T |
| 1-55 | 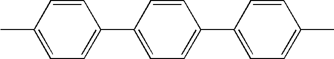 | 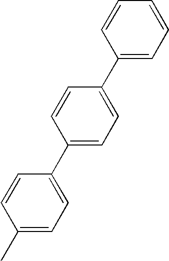 | 4 | 1 | T-20 |
| 1-56 | 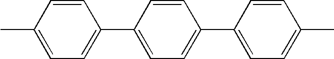 | 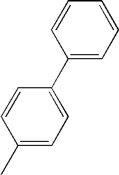 | 4 | 1 | T-24 |

TABLE 9

| Partial | | | Bonding | | |
|---|---|---|---|---|---|
| Structure | X | Ar | Position | k | T |
| 2-1 | 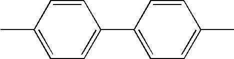 | 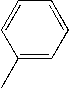 | 4,4′ | 0 | T-1 |
| 2-2 | 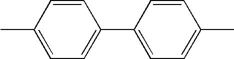 | 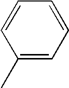 | 4,4′ | 0 | T-2 |
| 2-3 | 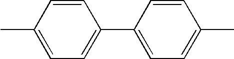 | 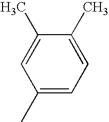 | 4,4′ | 0 | — |
| 2-4 | 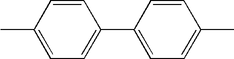 | 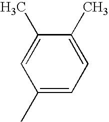 | 4,4′ | 0 | T-2 |
| 2-5 | 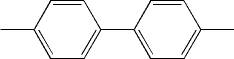 | 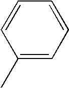 | 4,4′ | 1 | T-1 |
| 2-6 | 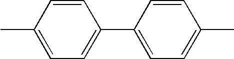 | 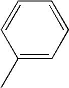 | 4,4′ | 1 | T-2 |

TABLE 10

| Partial | | | Bonding | | |
|---|---|---|---|---|---|
| Structure | X | Ar | Position | k | T |
| 2-7 | 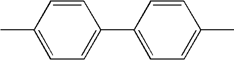 | 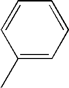 | 4,4′ | 1 | T-5 |
| 2-8 | 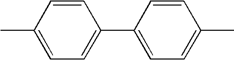 | 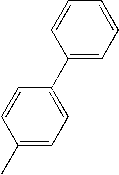 | 4,4′ | 1 | T-2 |
| 2-9 | 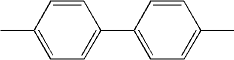 | 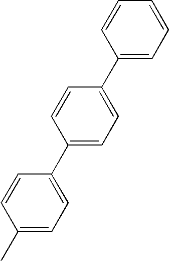 | 4,4′ | 1 | T-2 |
| 2-10 | 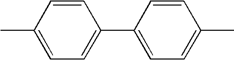 | 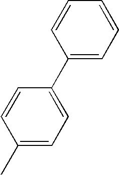 | 4,4′ | 1 | T-8 |
| 2-11 | 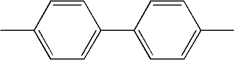 | 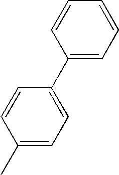 | 4,4′ | 1 | T-25 |
| 2-12 | 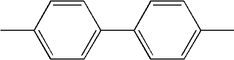 | 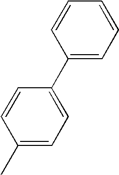 | 4,4′ | 1 | T-5 |

TABLE 11

| Partial | | | Bonding | | |
|---|---|---|---|---|---|
| Structure | X | Ar | Position | k | T |
| 2-13 | 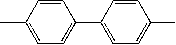 | 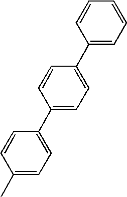 | 4, 4′ | 1 | T-1 |
| 2-14 | 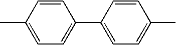 | 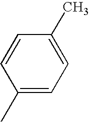 | 4, 4′ | 1 | T-2 |
| 2-15 | 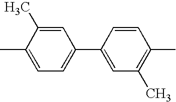 | 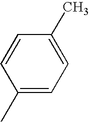 | 4, 4′ | 1 | — |
| 2-16 | 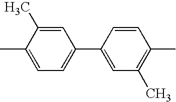 | 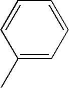 | 4, 4′ | 1 | T-2 |
| 2-17 | 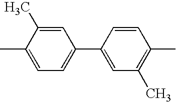 | 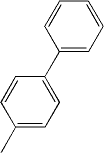 | 4, 4′ | 1 | T-2 |

TABLE 12

| Partial | | | Bonding | | |
|---|---|---|---|---|---|
| Structure | X | Ar | Position | k | T |
| 2-18 | 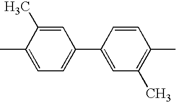 | 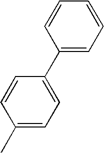 | 4, 4′ | 1 | T-1 |
| 2-19 | 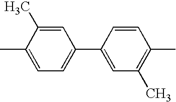 | 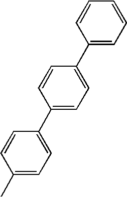 | 4, 4′ | 1 | T-2 |
| 2-20 | 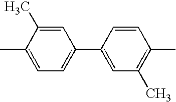 | 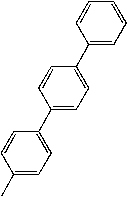 | 4, 4′ | 1 | T-4 |
| 2-21 | 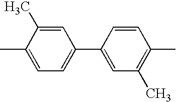 | 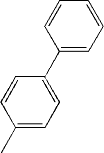 | 4, 4′ | 1 | T-5 |
| 2-22 | 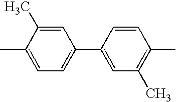 | 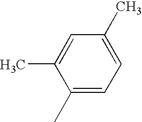 | 4, 4′ | 1 | T-5 |

TABLE 13

| Partial | | | Bonding | | |
|---|---|---|---|---|---|
| Structure | X | Ar | Position | k | T |
| 2-23 | 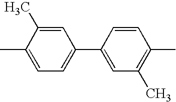 | 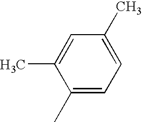 | 4, 4′ | 1 | T-13 |
| 2-24 | 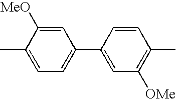 | 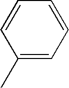 | 4, 4′ | 1 | — |
| 2-25 | 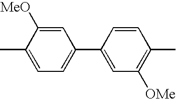 | 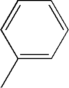 | 4, 4′ | 1 | T-2 |
| 2-26 | 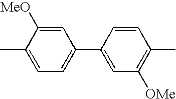 | 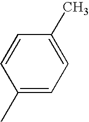 | 4, 4′ | 1 | T-2 |
| 2-27 | 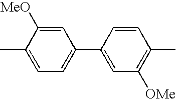 | 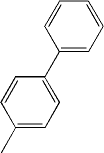 | 4, 4′ | 1 | T-2 |
| 2-28 | 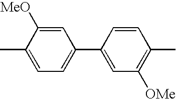 | 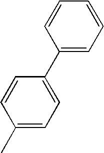 | 4, 4′ | 1 | T-8 |

TABLE 14

| Partial | | | Bonding | | |
|---|---|---|---|---|---|
| Structure | X | Ar | Position | k | T |
| 2-29 | 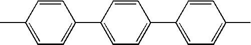 | 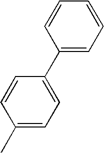 | 4, 4′ | 1 | T-2 |
| 2-30 | 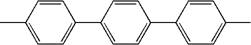 | 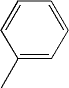 | 4, 4′ | 1 | T-2 |
| 2-31 | 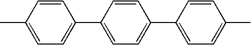 | 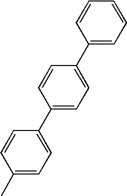 | 4, 4′ | 1 | T-2 |
| 2-32 | 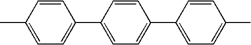 | 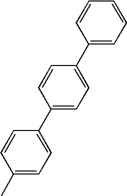 | 4, 4′ | 1 | T-5 |
| 2-33 | 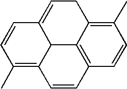 | 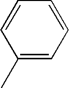 | 4, 4′ | 1 | T-2 |
| 2-34 | 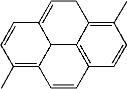 | 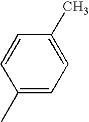 | 4, 4′ | 1 | T-8 |

TABLE 15

| Partial | | | Bonding | | |
|---|---|---|---|---|---|
| Structure | X | Ar | Position | k | T |
| 2-35 | 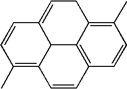 | 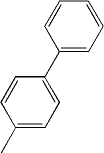 | 4, 4′ | 1 | T-18 |
| 2-36 | 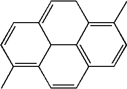 | 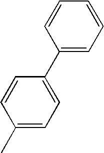 | 4, 4′ | 1 | T-20 |
| 2-37 | 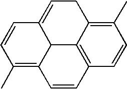 | 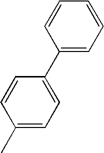 | 4, 4′ | 1 | T-24 |
| 2-38 | 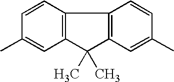 | 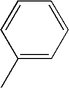 | 4, 4′ | 1 | T-2 |
| 2-39 | 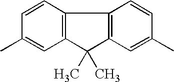 | 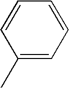 | 4, 4′ | 1 | T-8 |
| 2-40 | 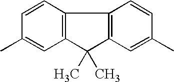 | 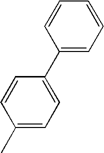 | 4, 4′ | 1 | T-18 |

TABLE 16

| Partial | | | Bonding | | |
|---|---|---|---|---|---|
| Structure | X | Ar | Position | k | T |
| 2-41 | 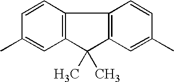 | 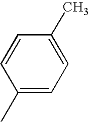 | 4, 4′ | 1 | T-20 |
| 2-42 | 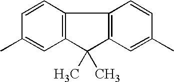 | 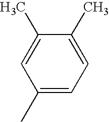 | 4, 4′ | 1 | T-24 |

The hole transport polymer containing at least one selected from the structures represented by formula (I-1) and formula (I-2) in the structure of the repeating unit thereof is preferably a hole transport polyester or hole transport polycarbonate having a repeating structure represented by any one of the following formulas (II), (III), (IV), and (V).

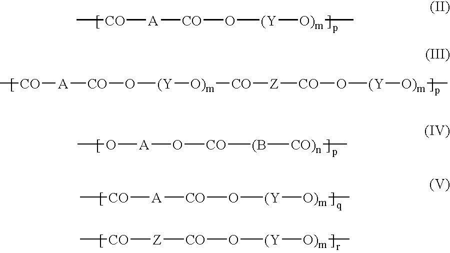

In formulas (II), (III), (IV), and (V), A is formula (I-1) or (I-2), and B is —O—(Y′O—)_{m′}—, or Z′, and each of m and m′ is an integer of 1 to 5, and n is 0 or 1, and p is an integer of 5 to 500, and q is an integer of 1 to 5000, and r is an integer of 1 to 3500.

In formulas (II), (III), (IV), and (V), each of Y, Y′, Z, and Z′ is a divalent hydrocarbon group. Specific examples of Y, Y′, Z, and Z′ include the following hydrocarbon groups (18) to (24).

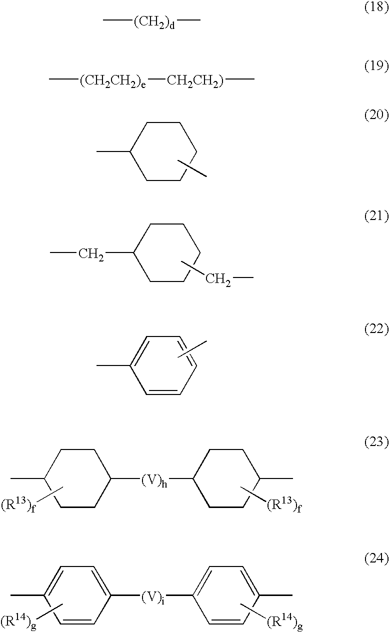

In the hydrocarbon groups (18) to (24), each of d and e is an integer of 1 to 10, and each of f and g is 0, 1 or 2, and each of h and i is 0 or 1.

R¹³ and R¹⁴ each represent a hydrogen atom, an alkyl group having 1 to 4 carbon atoms, an alkoxy group having 1 to 4 carbon atoms, a substituted or unsubstituted phenyl group, a substituted or unsubstituted aralkyl group, or a halogen atom, and V is selected from the groups of formulas (8) to (17).

Specific examples of the hole transport polymer represented by formula (II) are shown in Table 17, and specific examples of the hole transport polymer represented by formula (III) are shown in Table 18. Specific examples of the hole transport polymer represented by formula (IV) are shown in Table 19, and specific examples of the hole transport polymer represented by formula (V) are shown in Tables 20 to 24.

The hole transport polymer in the invention is not limited to these specific examples.

In Tables 17 to 24, the numerals shown in the column of “Structure” of the column of “Partial Structure” correspond to the compounds having numerals shown in the column of “Partial Structure” in Tables 1 to 16 (the specific examples of the structures of formulas (I-1) and (I-2)). When two or more numerals are shown in the column of “Structure” in Tables 17 to 24, the ratio of the compounds corresponding to the numerals in the molecule is indicated in the column of “Ratio” of the column of “Partial Structure”.

In Table 17, the structures shown in column Y correspond to Y in formula (II), the numerical values in column m correspond to m in formula (II), and the numerical values in column p correspond to p in formula (II).

In Table 18, the structures shown in column Y correspond to Y in formula (III), the structures shown in column Z correspond to Z in formula (III), the numerical values in column m correspond to m in formula (III), and the numerical values in column p correspond to p in formula (III).

In Table 19, the structures shown in column B correspond to B in formula (IV), the numerical values in column n correspond to n in formula (IV), and the numerical values in column p correspond to p in formula (IV).

In Tables 20 to 24, the structures shown in column Y correspond to Y in formula (V), the structures shown in column Z correspond to Z in formula (V), the numerical values in column m correspond to m in formula (V), the numerical values in column q correspond to q in formula (V), and the numerical values in column r correspond to r in formula (V).

In the following explanation, the compound corresponding to the mark X shown in the column of “Compound” in Tables 17 to 24 is indicated as “exemplary compound (X).”

TABLE 17

| | Partial Structure | | | | |
|---|---|---|---|---|---|
| Compound | Structure | Ratio | Y | m | p |
| CTP-1 | 1-6 | — | —CH₂CH₂— | 1 | 50 |
| CTP-2 | 1-6 | — | —CH₂CH₂— | 2 | 70 |
| CTP-3 | 1-6 | — | 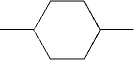 | 1 | 50 |
| CTP-4 | 1-6 | — | 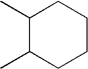 | 1 | 60 |
| CTP-5 | 1-6 | — | 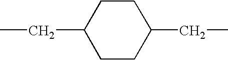 | 1 | 30 |
| CTP-6 | 1-8 | — | —CH₂CH₂— | 1 | 70 |
| CTP-7 | 1-9 | — | —CH₂CH₂— | 1 | 60 |
| CTP-8 | 1-14 | — | —CH₂CH₂— | 1 | 50 |
| CTP-9 | 1-16 | — | —CH₂CH₂— | 1 | 70 |
| CTP-10 | 1-21 | — | —CH₂CH₂— | 2 | 70 |
| CTP-11 | 1-21 | — | —CH₂CH₂— | 1 | 60 |
| CTP-12 | 2-6 | — | —CH₂CH₂— | 1 | 50 |
| CTP-13 | 2-8 | — | —CH₂CH₂— | 1 | 80 |
| CTP-14 | 2-9 | — | —CH₂CH₂— | 1 | 50 |
| CTP-15 | 2-14 | — | —CH₂CH₂— | 1 | 80 |
| CTP-16 | 2-16 | — | —CH₂CH₂— | 1 | 90 |
| CTP-17 | 2-17 | — | —CH₂CH₂— | 1 | 60 |
| CTP-18 | 1-6/1-14 | 1/1 | —CH₂CH₂— | 1 | 50 |
| CTP-19 | 1-6/2-6 | 1/1 | —CH₂CH₂— | 1 | 80 |
| CTP-20 | 1-22/2-8 | 1/1 | —CH₂CH₂— | 1 | 70 |
| CTP-21 | 1-22/2-14 | 1/1 | —CH₂CH₂— | 1 | 80 |
| CTP-22 | 1-22/2-6 | 1/1 | —CH₂CH₂— | 1 | 50 |
| CTP-108 | 1-29 | — | —CH₂CH₂— | 1 | 50 |

TABLE 18

| | Partial Structure | | | | | |
|---|---|---|---|---|---|---|
| Compound | Structure | Ratio | Y | Z | m | p |
| CTP-23 | 1-6 | — | —CH₂CH₂— | 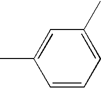 | 1 | 20 |
| CTP-24 | 1-6 | — | —CH₂CH₂— | 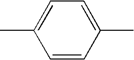 | 2 | 20 |
| CTP-25 | 1-19 | — | —CH₂CH₂— | 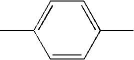 | 1 | 35 |
| CTP-26 | 1-19 | — | —CH₂CH₂— | —CH₂CH₂— | 1 | 45 |
| CTP-27 | 1-19 | — | 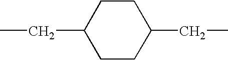 | 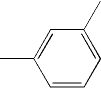 | 1 | 20 |
| CTP-28 | 2-6 | — | —CH₂CH₂— | 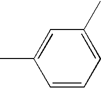 | 1 | 15 |

TABLE 19

| | Partial Structure | | | | |
|---|---|---|---|---|---|
| Compound | Structure | Ratio | B | n | p |
| CTP-29 | 1-6 | — | —O—CH₂CH₂—O— | 1 | 70 |
| CTP-30 | 1-6 | — | —O—(CH₂CH₂—O)₂— | 1 | 80 |
| CTP-31 | 1-6 | — | —CH₂CH₂— | 1 | 90 |
| CTP-32 | 1-6 | — | —(CH₂)₈— | 1 | 70 |
| CTP-33 | 1-14 | — | —O—(CH₂CH₂—O)₂— | 1 | 60 |
| CTP-34 | 1-19 | — | — | 0 | 70 |
| CTP-35 | 1-22 | — | — | 0 | 60 |

TABLE 20

| | Partial Structure | | | | | | |
|---|---|---|---|---|---|---|---|
| Compound | Structure | Ratio | Y | m | Z | q | r |
| CTP-36 | 1-6 | — | —CH₂CH₂— | 1 | —(CH₂)₄— | 80 | 40 |
| CTP-37 | 1-6 | — | —CH₂CH₂— | 2 | —(CH₂)₄— | 50 | 10 |
| CTP-38 | 1-6 | — | —CH₂CH₂— | 1 | —(CH₂)₈— | 60 | 30 |
| CTP-39 | 1-6 | — | —CH₂CH₂— | 1 | 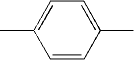 | 70 | 60 |
| CTP-40 | 1-6 | — | —CH₂CH₂— | 1 | 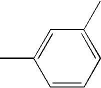 | 80 | 70 |
| CTP-41 | 1-8 | — | —CH₂CH₂— | 1 | —(CH₂)₂— | 100 | 40 |
| CTP-42 | 1-8 | — | —CH₂CH₂— | 1 | —(CH₂)₄— | 80 | 80 |
| CTP-43 | 1-8 | — | —CH₂CH₂— | 2 | —(CH₂)₈— | 40 | 40 |

TABLE 21

| | Partial Structure | | | | | | |
|---|---|---|---|---|---|---|---|
| Compound | Structure | Ratio | Y | m | Z | q | r |
| CTP-44 | 1-8 | — | —CH₂CH₂— | 1 | 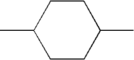 | 40 | 40 |
| CTP-45 | 1-14 | — | —CH₂CH₂CH₂— | 1 | —(CH₂)₄— | 60 | 30 |
| CTP-46 | 1-14 | — | —CH₂CH₂— | 1 | —(CH₂)₈— | 80 | 30 |
| CTP-47 | 1-16 | — | —CH₂CH₂— | 1 | —(CH₂)₂— | 80 | 10 |
| CTP-48 | 1-16 | — | —CH₂CH₂— | 1 | —(CH₂)₁₀— | 100 | 50 |
| CTP-49 | 1-19 | — | —CH₂CH₂— | 1 | —(CH₂)₂— | 80 | 30 |
| CTP-50 | 1-19 | — | —CH₂CH₂— | 1 | —(CH₂)₄— | 70 | 50 |
| CTP-51 | 1-19 | — | —CH₂CH₂— | 1 | —(CH₂)₈— | 90 | 80 |
| CTP-52 | 1-19 | — | —CH₂CH₂— | 1 | 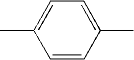 | 60 | 30 |
| CTP-53 | 1-19 | — | —CH₂CH₂— | 1 | 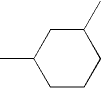 | 70 | 40 |
| CTP-54 | 1-21 | — | —CH₂CH₂— | 1 | —(CH₂)₄— | 100 | 40 |
| CTP-55 | 1-21 | — | —CH₂CH₂— | 2 | —(CH₂)₄— | 60 | 20 |
| CTP-56 | 1-22 | — | —CH₂CH₂— | 1 | —(CH₂)₂— | 100 | 30 |
| CTP-57 | 1-22 | — | —CH₂CH₂— | 1 | —(CH₂)₄— | 90 | 60 |
| CTP-58 | 1-22 | — | —CH₂CH₂— | 1 | —(CH₂)₈— | 70 | 70 |

TABLE 22

| | Partial Structure | | | | | | |
|---|---|---|---|---|---|---|---|
| Compound | Structure | Ratio | Y | m | Z | q | r |
| CTP-59 | 1-22 | — | —CH₂CH₂— | 1 | 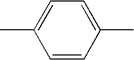 | 70 | 40 |
| CTP-60 | 1-22 | — | —CH₂CH₂— | 1 | 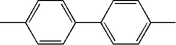 | 80 | 80 |
| CTP-61 | 1-29 | — | —CH₂CH₂— | 2 | —(CH₂)₁₀— | 50 | 30 |
| CTP-62 | 1-30 | — | —CH₂CH₂— | 1 | —(CH₂)₈— | 80 | 40 |
| CTP-63 | 1-31 | — | —CH₂CH₂— | 1 | 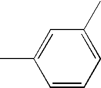 | 60 | 30 |
| CTP-64 | 1-31 | — | —CH₂CH₂— | 1 | —(CH₂)₂— | 80 | 30 |
| CTP-65 | 1-31 | — | —CH₂CH₂— | 1 | —(CH₂)₄— | 90 | 10 |
| CTP-66 | 1-32 | — | —CH₂CH₂— | 1 | —(CH₂)₄— | 80 | 50 |
| CTP-67 | 1-32 | — | —CH₂CH₂— | 1 | —(CH₂)₆— | 70 | 30 |
| CTP-68 | 1-37 | — | —CH₂CH₂— | 1 | —(CH₂)₈— | 60 | 20 |
| CTP-69 | 1-37 | — | —CH₂CH₂— | 3 | —(CH₂)₈— | 35 | 40 |
| CTP-70 | 2-6 | — | —CH₂CH₂CH₂— | 1 | —(CH₂)₈— | 80 | 60 |
| CTP-71 | 2-6 | — | —CH₂CH₂— | 1 | —(CH₂)₆— | 70 | 40 |
| CTP-72 | 2-8 | — | —CH₂CH₂— | 1 | —(CH₂)₄— | 80 | 30 |
| CTP-73 | 2-8 | — | —CH₂CH₂— | 2 | —(CH₂)₄— | 85 | 50 |
| CTP-74 | 2-8 | — | —CH₂CH₂— | 1 | —(CH₂)₈— | 100 | 30 |

TABLE 23

| | Partial Structure | | | | | | |
|---|---|---|---|---|---|---|---|
| Compound | Structure | Ratio | Y | m | Z | | r |
| CTP-75 | 2-9 | — | —CH₂CH₂— | 1 | —(CH₂)₂— | 90 | 60 |
| CTP-76 | 2-9 | — | —CH₂CH₂— | 1 | —(CH₂)₄— | 80 | 70 |
| CTP-77 | 2-9 | — | —CH₂CH₂— | 1 | —(CH₂)₈— | 50 | 40 |
| CTP-78 | 2-9 | — | —CH₂CH₂— | 1 | 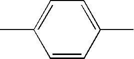 | 80 | 80 |
| CTP-79 | 2-14 | — | —CH₂CH₂— | 2 | —(CH₂)₄— | 40 | 80 |
| CTP-80 | 2-14 | — | —CH₂CH₂— | 1 | —(CH₂)₈— | 80 | 40 |
| CTP-81 | 2-14 | — | | 1 | 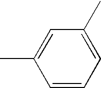 | 60 | 30 |
| CTP-82 | 2-19 | — | —CH₂CH₂— | 1 | —(CH₂)₄— | 80 | 30 |
| CTP-83 | 2-19 | — | —CH₂CH₂— | 1 | —(CH₂)₁₀— | 70 | 10 |
| CTP-84 | 2-29 | — | —CH₂CH₂— | 1 | —(CH₂)₄— | 50 | 50 |
| CTP-85 | 2-29 | — | —CH₂CH₂— | 1 | —(CH₂)₆— | 80 | 10 |
| CTP-86 | 2-30 | — | —CH₂CH₂— | 1 | —(CH₂)₈— | 60 | 20 |
| CTP-87 | 2-30 | — | —CH₂CH₂— | 1 | 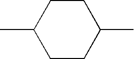 | 80 | 40 |
| CTP-88 | 2-31 | — | —CH₂CH₂CH₂— | 1 | —(CH₂)₄— | 80 | 60 |
| CTP-89 | 2-31 | — | —CH₂CH₂— | 1 | —(CH₂)₈— | 80 | 40 |
| CTP-90 | 2-33 | — | —CH₂CH₂— | 1 | —(CH₂)₄— | 70 | 40 |

TABLE 24

| | Partial Structure | | | | | | |
|---|---|---|---|---|---|---|---|
| Compound | Structure | Ratio | Y | m | Z | q | r |
| CTP-91 | 2-36 | — | —CH₂CH₂— | 2 | —(CH₂)₄— | 70 | 30 |
| CTP-92 | 2-39 | — | —CH₂CH₂— | 1 | —(CH₂)₈— | 150 | 30 |
| CTP-93 | 2-39 | — | —CH₂CH₂— | 1 | 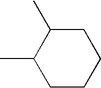 | 90 | 60 |
| CTP-94 | 1-6/1-18 | 1/1 | —CH₂CH₂— | 1 | 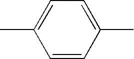 | 110 | 70 |
| CTP-95 | 1-6/1-20 | 1/1 | —CH₂CH₂— | 1 | —(CH₂)₂— | 110 | 40 |
| CTP-96 | 1-6/1-20 | 1/1 | —CH₂CH₂— | 1 | —(CH₂)₄— | 85 | 85 |
| CTP-97 | 1-6/2-6 | 1/1 | —CH₂CH₂— | 2 | —(CH₂)₄— | 45 | 30 |
| CTP-98 | 1-19/1-22 | 1/1 | —CH₂CH₂— | 1 | —(CH₂)₈— | 80 | 40 |
| CTP-99 | 1-19/1-26 | 2/1 | | 1 | 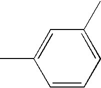 | 60 | 30 |
| CTP-100 | 1-19/1-33 | 1/1 | —CH₂CH₂— | 1 | —(CH₂)₄— | 130 | 30 |
| CTP-101 | 1-19/1-38 | 2/1 | —CH₂CH₂— | 1 | —(CH₂)₁₀— | 130 | 10 |
| CTP-102 | 2-4/2-6 | 1/1 | —CH₂CH₂— | 1 | —(CH₂)₄— | 115 | 50 |
| CTP-103 | 2-5/2-6 | 1/1 | —CH₂CH₂— | 1 | —(CH₂)₆— | 120 | 30 |
| CTP-104 | 2-6/2-19 | 1/1 | | 3 | —(CH₂)₈— | 30 | 20 |
| CTP-105 | 2-19/2-29 | 1/1 | —CH₂CH₂— | 1 | —(CH₂)₈— | 80 | 40 |
| CTP-106 | 2-19/2-22 | 1/1 | —CH₂CH₂CH₂— | 1 | —(CH₂)₆— | 80 | 60 |
| CTP-107 | 2-35/2-31 | 1/1 | —CH₂CH₂— | 1 | —(CH₂)₈— | 110 | 40 |

The hole transport layer of the organic electroluminescence device of the first aspect preferably contains at least one of the above hole transport polymers, and at least one electron transport material.

Specific examples of the electron transport material mixed with the hole transport polymer of the hole transport layer of the organic electroluminescence device of the first aspect include condensed polynuclear cyclic compounds such as anthracene derivatives, pyrene derivatives, and perylene derivatives, oxazole derivatives, thiazole derivatives, oxadiazole derivatives, metal chelate complex compounds such as tris(8-quinolinolato) aluminum derivatives, nitro-substituted fluorenone derivatives, diphenoquinone derivatives, thiopyran dioxide derivatives, and fluorenilidene methane derivatives. The electron transport material mixed with the hole transport material of the hole transport layer may also be a luminescent material.

Among the electron transport materials, the electron transport material mixed with the hole transport material of the hole transport layer of the organic electroluminescence device of the first aspect is preferably a luminescent material from the viewpoint of elevation of efficiency of luminescence. When a luminescent material serving as the electron transport material is mixed with the hole transport layer, luminescent reaction occurs not only in the luminescent layer, but also in the hole transport layer in which the luminescent material is mixed, and the efficiency of luminescence can be enhanced.

This luminescent material may also be used as a material for the luminescent layer of the organic electroluminescence device of the first aspect.

When an organic low molecular weight luminescent material is used to form a luminescent layer, it is necessary that a good thin luminescent film can be formed by vacuum-depositing the luminescent material or by applying a solution or dispersion liquid containing the low molecular weight luminescent material and a binder resin, and drying the resultant coating. When an organic high molecular weight luminescent material (that may be referred to as a luminescent polymer) is used to form a luminescent layer, it is necessary that a good thin luminescent film can be formed by applying a solution or dispersion liquid containing the high molecular weight luminescent material, and drying the resultant coating.

When a luminescent material serving as an electron transport material is contained in the hole transport layer, the luminescent material is preferably an organic compound that hardly shows strong electronic interaction with the hole transport material (e.g., polymer) of the hole transport layer. When such a luminescent material is an organic low molecular weight compound, specific examples thereof include chelate-type metal complexes, polynuclear or condensed aromatic ring compounds, perylene derivatives, coumarine derivatives, styrylarylene derivatives, silole derivatives, oxazole derivatives, oxathiazole derivatives, and oxadiazole derivatives.

In the case of a high molecular weight luminescent material, examples thereof include a pi-conjugate polymer, a dye-containing polymer, and a non-conjugate polymer. The luminescent polymer is preferably a pi-conjugate polymer. The pi-conjugate polymer has a structure in which double bonds and single bonds are alternately arranged, and typical examples thereof in the invention include those obtained by direct bonding between aromatic rings or hetero aromatic rings such as a benzene ring, a naphthalene ring, a thiophene ring, a pyrolle ring, or a furan ring that may have at least one substituent, or indirect bonding of such aromatic or hetero aromatic rings via a vinylene group therebetween, wherein the vinylene group may have at least one substituent.

The pi-conjugate polymer is preferably a polyparaphenylene derivative, a polyparaphenylene vinylene derivative, a polythiophene derivative, a polyacetylene derivative, or a polyfluorene derivative. Specific examples thereof include unsubstituted or substituted fluorene, unsubstituted or substituted thiophene, unsubstituted or substituted vinylene, unsubstituted or substituted thienylene vinylene, unsubstituted or substituted phenylene vinylene, and unsubstituted or substituted p-phenylene. Also, the pi-conjugate polymer is an oligomer that has, as repeating units, at least two of unsubstituted or substituted fluorene, unsubstituted or substituted thiophene, unsubstituted or substituted vinylene, unsubstituted or substituted thienylene vinylene, unsubstituted or substituted phenylene vinylene, and unsubstituted or substituted p-phenylene moieties and whose number x of repetition is an integer of 4 to 10, or a high molecular compound that has, as repeating units, at least two of unsubstituted or substituted fluorene, unsubstituted or substituted thiophene, unsubstituted or substituted vinylene, unsubstituted or substituted thienylene vinylene, unsubstituted or substituted phenylene vinylene, and unsubstituted or substituted p-phenylene moieties and whose number x of repetition is an integer of 10 or more.

Typical examples of the luminescent polymer serving as an electron transport material mixed in the hole transport layer of the organic electroluminescence device of the first aspect include, but are not limited to, the following compounds (VI-1) to (VI-15).

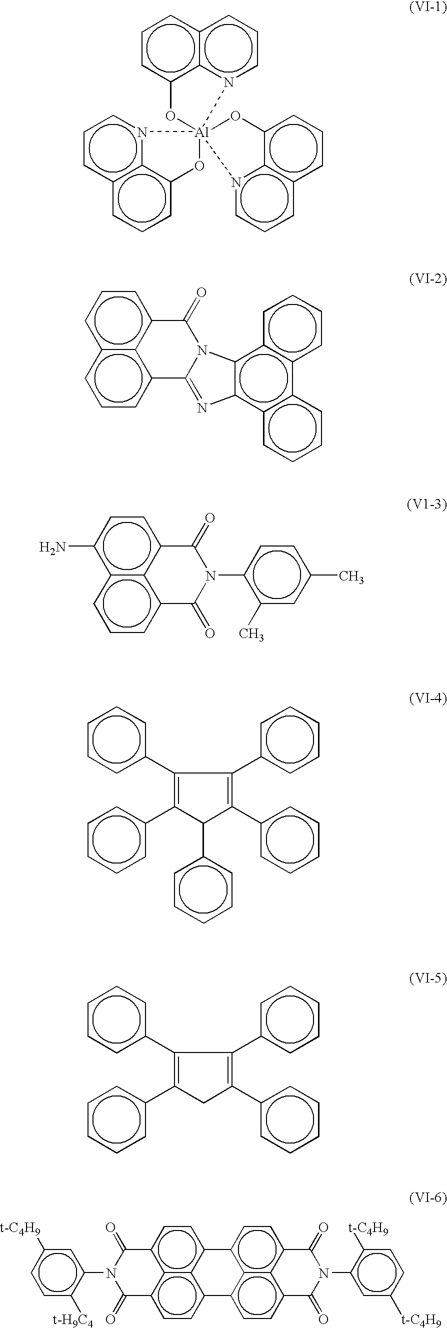

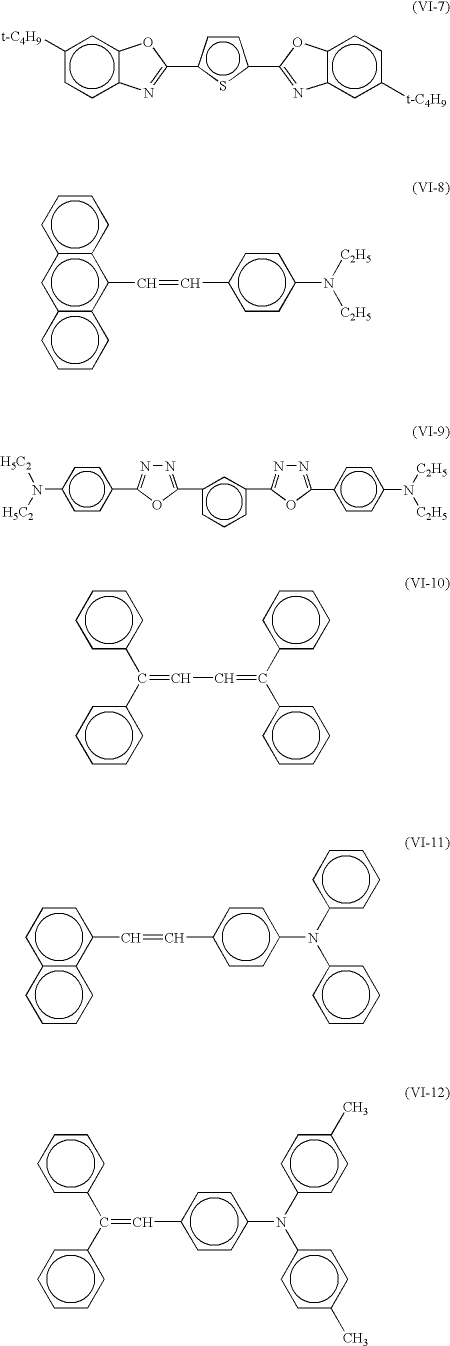

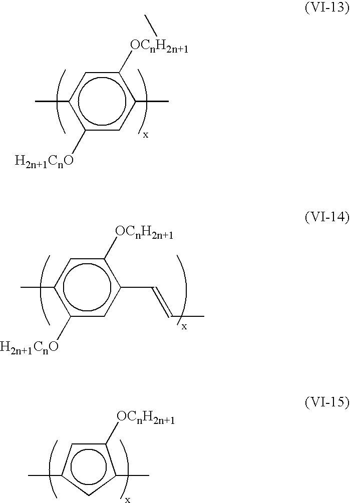

In order to ensure a sufficient hole mobility required for the hole transport layer of the organic electroluminescence device of an aspect, the amount of the electron transport material mixed with the hole transport polymer is preferably in the range of about 0.01 parts by mass to about 50 parts by mass, and more preferably in the range of about 0.05 parts by mass to about 30 parts by mass with respect to 100 parts by mass of the hole transport material of the hole transport layer.

When the amount of the electron transport material mixed with the hole transport polymer of the hole transport layer is less than about 0.01 parts by mass, the hole transport layer may not obtain an electron transport ability. When the amount of the electron transport material is more than about 50 parts by mass, the hole transport layer may have a deteriorated hole transport ability.

In order to enhance the durability or the luminescent efficiency of the organic electroluminescence device, when the luminescent layer includes a luminescent material, the luminescent layer may further contain, as a guest material with which the luminescent material is doped, a dye different from the luminescent material.

When the luminescent layer is formed by vacuum deposition, such doping can be conducted by co-depositing the luminescent material and the dye. When the luminescent layer is formed by applying and driving a solution or dispersion liquid, the doping can be conducted by mixing the luminescent material and the dye with the solution or dispersion liquid. The content of the dye compound, which is used in the doping, in the luminescent layer is generally in the range of about 0.001 mass % to about 40 mass %, and preferably in the range of about 0.001 mass % to about 10 mass %. The dye compound used in such doping is an organic compound compatible with the luminescent material and not preventing formation of a good thin luminescent layer (film), and is preferably a DCM derivative, a quinacridone derivative, a rubrene derivative, or porphiline. Specific examples thereof include, but are not limited to the following compounds (VII-1) to (VII-4).

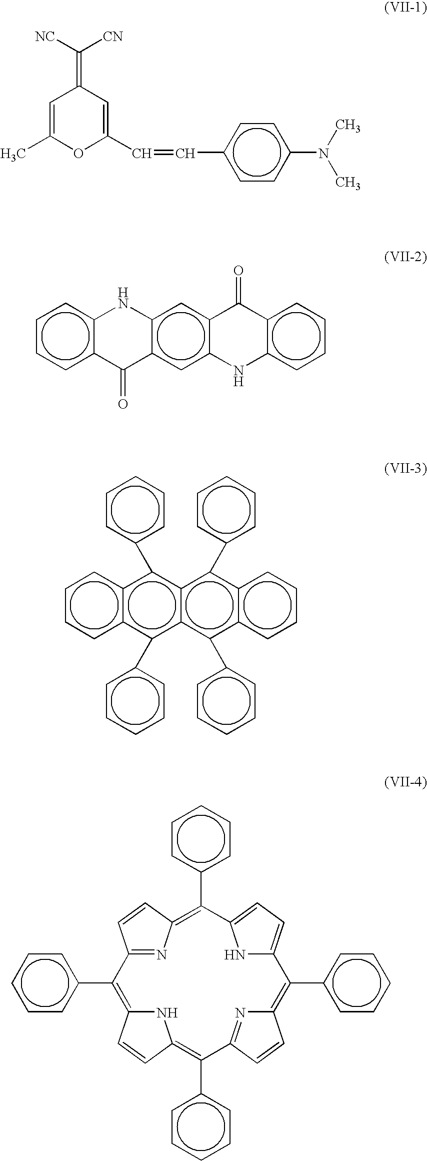

The luminescent layer can be formed by vacuum deposition or by applying and drying a solution or a dispersion liquid. However, when at least one material not forming a good thin film or not showing a clear electron transport property is used in the luminescent layer, an electron transport layer 26 may be disposed between a luminescent layer 24 and a back electrode 30, as shown in FIG. 1 and FIG. 2, in order to enhance the durability or the luminescent efficiency of the organic electroluminescence device.

The electron transport layer of the organic electroluminescence device of the invention has a function of receiving electrons from the cathode or the cathode side thereof, and transporting the electrons to the anode side thereof, or the luminescent layer. Accordingly, the electron mobility of the electron transport material of the electron transport layer is preferably in the range of about 1×10⁻⁸ cm²/(Vs) to about 1×10⁻² cm²/(Vs).

The electron mobility is obtained by measuring a transient light current waveform with respect to the moving amount of charged carriers, and calculating the hole mobility from the applied voltage and the thickness of a sample used in the measurement at this time. This is a method for measuring the mobility of charged carriers generally known in this technical field as a so-called time-of-flight method (TOF method).

When the electron transport material used in the electron transport layer 26 is an organic low molecular weight compound, the electron transport material is preferably an organic compound capable of forming a good thin film by vacuum deposition method. Specific examples thereof include oxadiazole derivatives, nitro-substituted fluorenone derivatives, diphenoquinone derivatives, thiopyran dioxide derivatives, and fluorenilidene methane derivatives. When the electron transport material is a polymer, it is necessary that a good thin luminescent film can be formed by applying a solution or dispersion liquid containing the electron transport material.

Specific examples of the electron transport material used in the electron transport layer 26 include, but re not limited to, the following compounds (VIII-1) to (VIII-3), and (IX). The electron transport material may also be mixed with any other resin(s) for general purpose.

The same electron transport material may be used in both the electron transport layer and the hole transport layer.

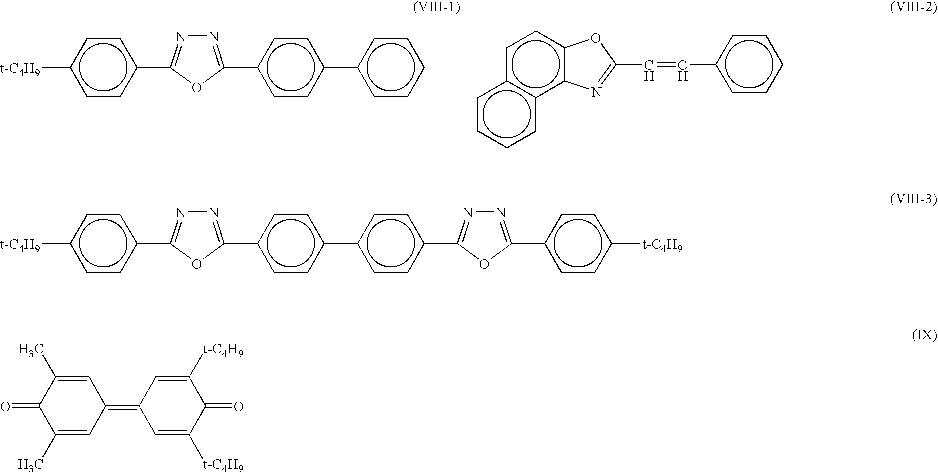

When the electron transport material used in the electron transport layer of the organic electroluminescence device of the first aspect is an electron transport polymer, the polymer preferably has at least one partial structure represented by the following formula (X-1) as the structure of the repeating unit thereof

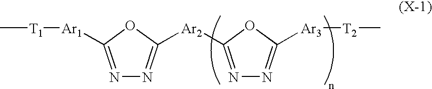

In formula (X-1), each of Ar₁, Ar₂, and Ar₃ represents a substituted or unsubstituted arylene group, a divalent hetero ring group, or a group including a combination of them. In formula (X-1), each of T₁ and T₂ represents a linear divalent hydrocarbon group having 1 to 10 carbon atoms, or a branched divalent hydrocarbon group having 1 to 10 carbon atoms, and n is an integer of 3 to 5.

The arylene group for Ar₁, Ar₂, and Ar₃ in formula (X-1) is a monocyclic or condensed ring arylene group. Such an arylene group preferably has 6 to 60 carbon atoms, more preferably 6 to 40 carbon atoms, and still more preferably 6 to 30 carbon atoms.

Specific examples of the arylene group for Ar₁, Ar₂, and Ar₃ in formula (X-1) include a phenylene group, a biphenylene group, a triphenylene group, a tetraphenylene group, a naphthalenediyl group, an anthracenediyl group, a phenanthrolinediyl group, a pyrenediyl group, a triphenylenediyl group, a benzophenantrolinediyl group, a perylenediyl group, a pentaphenylenediyl group, and a pentacenediyl group. The arylene group is preferably a phenylene group, a biphenylene group, a naphthalenediyl group, an anthracenediyl group, a pyrenediyl group, or a perylenediyl group, and more preferably a phenylene group, a biphenylene group, or a triphenylene group.

The divalent hetero ring group for Ar₁, Ar₂, and Ar₃ in formula (X-1) is preferably a monocyclic or condensed hetero ring group having 4 to 60 carbon atoms, more preferably a monocyclic or condensed hetero ring group having 4 to 60 carbon atoms and containing at least one of nitrogen, oxygen, and sulfur atoms, and still more preferably a five- or six-membered hetero ring group having 4 to 30 carbon atoms.

Examples of the divalent hetero ring group for Ar₁, Ar₂, and Ar₃ in formula (X-1) include a pyrrolediyl group, a furanediyl group, a thienylene group, a pyridinediyl group, a pyridazinediyl group, a pyrimidinediyl group, a pyrazinediyl group, a quinolinediyl group, an isoquinolinediyl group, a cinnolinediyl group, a quinazolinediyl group, a quinoxalinediyl group, a phthalazinediyl group, a pteridinediyl group, an acrylidinediyl group, a phenazinediyl group, and a phenanthrolinediyl group. The divalent hetero ring group is preferably a furanediyl group, a thienylene group, a pyridinediyl group, a pyridazinediyl group, a pyrimidinediyl group, a pyrazinediyl group, a quinolinediyl group, a quinoxalinediyl group, or a phthalazinediyl group, and more preferably a thienylene group or a pyridinediyl group.

The arylene group or hetero group for Ar₁, Ar₂, and Ar₃ in formula (X-1) may have at least one substituent. Examples of the at least one substituent include alkyl groups preferably having 1 to 20 carbon atoms, more preferably 1 to 12 carbon atoms, and still more preferably 1 to 8 carbon atoms, for example, methyl, ethyl, isopropyl, tertbutyl, n-octyl, n-decyl, n-hexadecyl, cyclopropyl, cyclopentyl, and cyclohexyl groups; alkenyl groups preferably having 2 to 20 carbon atoms, more preferably 2 to 12 carbon atoms, and still more preferably 2 to 8 carbon atoms, for example, vinyl, allyl, 2-butenyl, and 3-pentenyl groups; alkynyl groups preferably having 2 to 20 carbon atoms, more preferably 2 to 12 carbon atoms, and still more preferably 2 to 8 carbon atoms, for example, propargyl, and 3-pentynyl groups; aryl groups preferably having 6 to 30 carbon atoms, more preferably 6 to 20 carbon atoms, and still more preferably 6 to 12 carbon atoms, for example, phenyl, p-methylphenyl, and naphtyl groups; amino groups preferably having 0 to 20 carbon atoms, more preferably 0 to 10 carbon atoms, and still more preferably 0 to 6 carbon atoms, for example, amino, methylamino, dimethylamino, diethylamino, and dibenzylamino groups; alkoxy groups preferably having 1 to 20 carbon atoms, more preferably 1 to 12 carbon atoms, and still more preferably 1 to 8 carbon atoms, for example, methoxy, ethoxy, and butoxy groups; aryloxy groups preferably having 6 to 20 carbon atoms, more preferably 6 to 16 carbon atoms, and still more preferably 6 to 12 carbon atoms, for example, phenyloxy and 2-naphthyloxy groups; acyl groups preferably having 1 to 20 carbon atoms, more preferably 1 to 16 carbon atoms, and still more preferably 1 to 12 carbon atoms, for example, acetyl, benzoyl, formyl, and pivaloyl groups; alkoxycarbonyl groups preferably having 2 to 20 carbon atoms, more preferably 2 to 16 carbon atoms, and still more preferably 2 to 12 carbon atoms, for example, methoxycarbonyl and ethoxycarbonyl groups; aryloxycarbonyl groups preferably having 7 to 20 carbon atoms, more preferably 7 to 16 carbon atoms, and still more preferably 7 to 10 carbon atoms, for example, a phenyloxycarbonyl group; acyloxy groups preferably having 2 to 20 carbon atoms, more preferably 2 to 16 carbon atoms, and still more preferably 2 to 10 carbon atoms, for example, acetoxy and benzoyloxy groups; acylamino groups preferably having 2 to 20 carbon atoms, more preferably 2 to 16 carbon atoms, and still more preferably 2 to 10 carbon atoms, for example, acetylamino and benzoylamino groups; alkoxycarbonylamino groups preferably having 2 to 20 carbon atoms, more preferably 2 to 16 carbon atoms, and still more preferably 2 to 12 carbon atoms, for example, a methoxycarbonylamino group; aryloxycarbonylamino groups preferably having 7 to 20 carbon atoms, more preferably 7 to 16 carbon atoms, and still more preferably 7 to 12 carbon atoms, for example, a phenyloxycarbonylamino group; sulfonylamino groups preferably having 1 to 20 carbon atoms, more preferably 1 to 16 carbon atoms, and still more preferably 1 to 12 carbon atoms, for example, methanesulfonylamino and benzenesulfonylamino groups; sulfamoyl groups preferably having 0 to 20 carbon atoms, more preferably 0 to 16 carbon atoms, and still more preferably 0 to 12 carbon atoms, for example, sulfamoyl, methylsulfamoyl, dimethylsulfamoyl, and phenylsulfamoyl groups; carbamoyl groups preferably having 1 to 20 carbon atoms, more preferably 1 to 16 carbon atoms, and still more preferably 1 to 12 carbon atoms, for example, carbamoyl, methylcarbamoyl, diethylcarbamoyl, and phenylcarbamoyl groups; alkylthio groups preferably having 1 to 20 carbon atoms, more preferably 1 to 16 carbon atoms, and still more preferably 1 to 12 carbon atoms, for example, methylthio and ethylthio groups; arylthio groups preferably having 6 to 20 carbon atoms, more preferably 6 to 16 carbon atoms, and still more preferably 6 to 12 carbon atoms, for example, a phenylthio group; sulfonyl groups preferably having 1 to 20 carbon atoms, more preferably 1 to 16 carbon atoms, and still more preferably 1 to 12 carbon atoms, for example, mesyl and tosyl groups; sulfinyl groups preferably having 1 to 20 carbon atoms, more preferably 1 to 16 carbon atoms, and still more preferably 1 to 12 carbon atoms, for example, methanesulfinyl and benzenesulfinyl groups; ureido groups preferably having 1 to 20 carbon atoms, more preferably 1 to 16 carbon atoms, and still more preferably 1 to 12 carbon atoms, for example, ureido, methylureido, and phenylureido groups; phosphoric amide groups preferably having 1 to 20 carbon atoms, more preferably 1 to 16 carbon atoms, and still more preferably 1 to 12 carbon atoms, for example, diethylphosphoric amide and phenylphosphoric amide groups; a hydroxy group; a mercapto group; halogen atoms (for example, a fluorine atom, a chlorine atom, a bromine atom, and an iodine atom); a cyano group; a sulfo group; a carboxyl group; a nitro group; a hydroxamic group; a sulfino group; a hydrazino group; an immino group; hetero ring groups preferably having 1 to 30 carbon atoms, and more preferably 1 to 12 carbon atoms, and having at least one hetero atom selected from nitrogen, oxygen, and sulfur atoms, for example imidazolyl, pyridyl, quinolyl, furyl, piperidyl, morpholino, benzoxazolyl, benzimidazolyl, and benzteazoyl groups; and silyl groups preferably having 3 to 40 carbon atoms, more preferably 3 to 30 carbon atoms, and still more preferably 3 to 24 carbon atoms, for example, trimethylsilyl and triphenylsilyl groups.

Each of these substituents may be further substituted. When the arylene group or the hetero ring group has two or more substituents, they may be the same or different. If possible, they may be bonded to each other to form another ring.

Each of the substituent(s) that replaces a hydrogen atom of each of the substituent(s) of the substituted hetero ring group is preferably an alkyl group, an alkenyl group, an aralkyl group, an aryl group, an alkoxy group, an aryloxy group, an alkylthio group, an arylthio group, a halogen atom, a cyano group, or a hetero ring group, more preferably an alkyl group, an aryl group, an alkoxy group, an aryloxy group, an alkylthio group, an aryltho group, or a hetero cyclic group, and still more preferably an aryl group or an aromatic hetero ring group.

The hetero ring group represented by Ar₂ in formula (X-1) is preferably a saturated or unsaturated three- to ten-membered hetero ring group having at least one of N, O and S atoms. Such a hetero ring group may be a monocyclic group or a condensed ring group in which the hetero ring group is combined with other ring group(s).

Specific examples of such a hetero ring include pyrrolidine, piperizine, piperazine, morpholine, thiophene, furane, pyrrole, imidazole, pyrazole, pyridine, pyrazine, pyridazine, pyrimidine, triazole, triazine, indole, indazole, purine, thiazoline, thiazole, thiadiazole, oxazoline, oxazole, oxadiazole, quinoline, isoquinoline, phthalazine, naphthylidine, quinoxaline, quinazoline, cinnoline, pteridine, acridine, phenanthroline, phenazine, tetrazole, benzimidazole, benzoxazole, benzothiazole, benzotriazole, and tetraazaindene.

The hetero ring group represented by Ar₂ in formula (X-1) is more preferably an aromatic five- or six-membered hetero ring group, still more preferably thiophene, furane, pyrrole, imidazole, pyrazole, pyridine, pyrimidine, thiazole, thiadiazole, oxazole, oxadiazole, quinoline, benzimidazole, benzoxazole, or benzothiazole, and still more preferably thiophene, furane, pyridine, pyrimidine, thiazole, thiadiazole, oxazoline, oxazole, oxadiazole, or quinoline.

In formula (X-1), each of T₁ and T₂ represents a linear divalent hydrocarbon group having 1 to 10 carbon atoms, or a branched divalent hydrocarbon group having 1 to 10 carbon atoms. These groups more preferably have 1 to 4 carbon atoms. Specific examples thereof include a methylene group, an ethylene group, a propylene group, and a butylene group.

Specific examples of the high molecular weight electron transport material represented by formula (X-1) are shown in Tables 25 to 41 (compound Nos. A1 to A119).

TABLE 25

| Compound | | | | | | |
|---|---|---|---|---|---|---|
| No. | n | Ar₁ | Ar₂ | Ar₃ | T₁ | T₂ |
| (A1) | 0 | 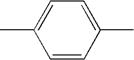 | 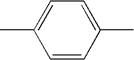 | — | —CH₂— | —CH₂— |
| (A2) | 0 | 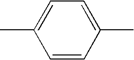 | 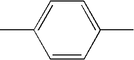 | — | —CH₂CH₂— | —CH₂CH₂— |
| (A3) | 0 | 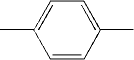 | 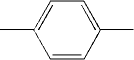 | — | —CH₂CH₂CH₂— | —CH₂CH₂CH₂— |
| (A4) | 0 | 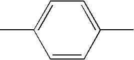 | 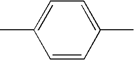 | — | 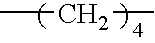 | 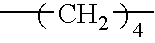 |
| (A5) | 0 | 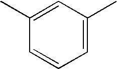 | 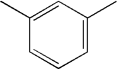 | — | —CH₂— | —CH₂— |
| (A6) | 0 | 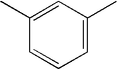 | 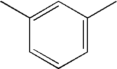 | — | —CH₂CH₂— | —CH₂CH₂— |
| (A7) | 0 | 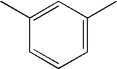 | 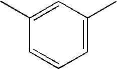 | — | —CH₂CH₂CH₂— | —CH₂CH₂CH₂— |
| (A8) | 0 | 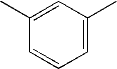 | 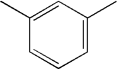 | — | 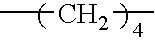 | 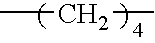 |
| (A9) | 0 | 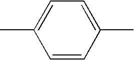 | 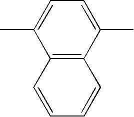 | — | —CH₂— | —CH₂— |

TABLE 26

| Compound | | | | | | |
|---|---|---|---|---|---|---|
| No. | n | Ar₁ | Ar₂ | Ar₃ | T₁ | T₂ |
| (A10) | 0 | 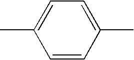 | 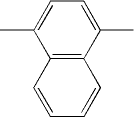 | — | —CH₂CH₂— | —CH₂CH₂— |
| (A11) | 0 | 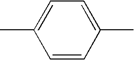 | 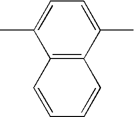 | — | —CH₂CH₂CH₂— | —CH₂CH₂CH₂— |
| (A12) | 0 | 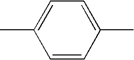 | 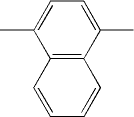 | — | 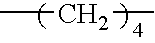 | 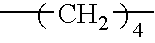 |
| (A13) | 0 | 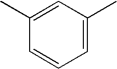 | 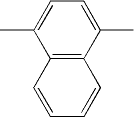 | — | —CH₂— | —CH₂— |
| (A14) | 0 | 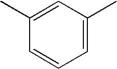 | 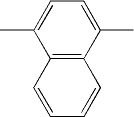 | — | —CH₂CH₂— | —CH₂CH₂— |
| (A15) | 0 | 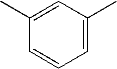 | 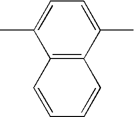 | — | —CH₂CH₂CH₂— | —CH₂CH₂CH₂— |
| (A16) | 0 | 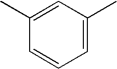 | 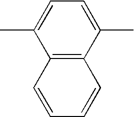 | — | 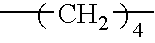 | 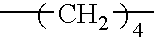 |

TABLE 27

| Compound | | | | | | |
|---|---|---|---|---|---|---|
| No. | n | Ar₁ | Ar₂ | Ar₃ | T₁ | T₂ |
| (A17) | 0 | 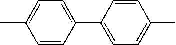 | 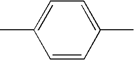 | — | —CH₂— | —CH₂— |
| (A18) | 0 | 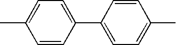 | 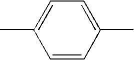 | — | —CH₂CH₂— | —CH₂CH₂— |
| (A19) | 0 | 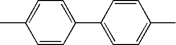 | 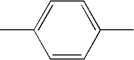 | — | —CH₂CH₂CH₂— | —CH₂CH₂CH₂— |
| (A20) | 0 | 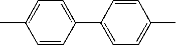 | 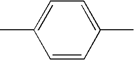 | — | 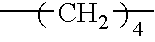 | 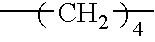 |
| (A21) | 0 | 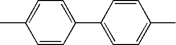 | 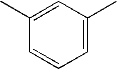 | — | —CH₂— | —CH₂— |
| (A22) | 0 | 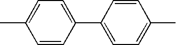 | 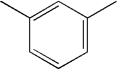 | — | —CH₂CH₂— | —CH₂CH₂— |
| (A23) | 0 | 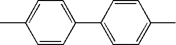 | 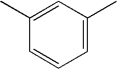 | — | —CH₂CH₂CH₂— | —CH₂CH₂CH₂— |
| (A24) | 0 | 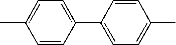 | 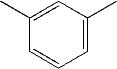 | — | 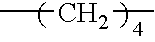 | 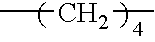 |
| (A25) | 0 | 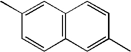 | 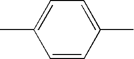 | — | —CH₂— | —CH₂— |

TABLE 28

| Compound | | | | | | |
|---|---|---|---|---|---|---|
| No. | n | Ar₁ | Ar₂ | Ar₃ | T₁ | T₂ |
| (A26) | 0 | 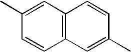 | 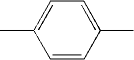 | — | —CH₂CH₂— | —CH₂CH₂— |
| (A27) | 0 | 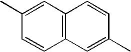 | 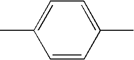 | — | —CH₂CH₂CH₂— | —CH₂CH₂CH₂— |
| (A28) | 0 | 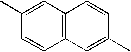 | 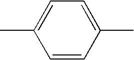 | — | 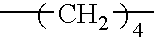 | 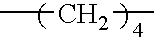 |
| (A29) | 0 | 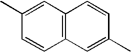 | 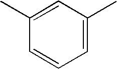 | — | —CH₂— | —CH₂— |
| (A30) | 0 | 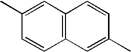 | 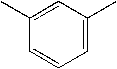 | — | —CH₂CH₂— | —CH₂CH₂— |
| (A31) | 0 | 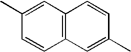 | 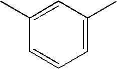 | — | —CH₂CH₂CH₂— | —CH₂CH₂CH₂— |
| (A32) | 0 | 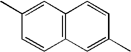 | 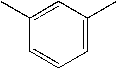 | — | 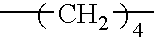 | 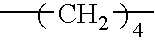 |
| (A33) | 0 | 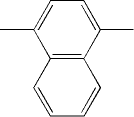 | 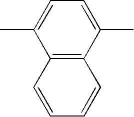 | — | —CH₂— | —CH₂— |
| (A34) | 0 | 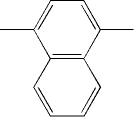 | 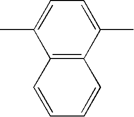 | — | —CH₂CH₂— | —CH₂CH₂— |

TABLE 29

| Compound | | | | | | |
|---|---|---|---|---|---|---|
| No. | n | Ar₁ | Ar₂ | Ar₃ | T₁ | T₂ |
| (A35) | 0 | 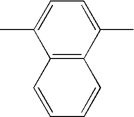 | 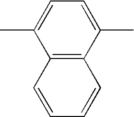 | — | —CH₂CH₂CH₂— | —CH₂CH₂CH₂— |
| (A36) | 0 | 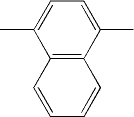 | 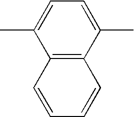 | — | 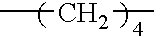 | 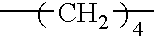 |
| (A37) | 0 | 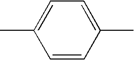 | 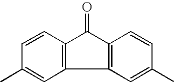 | — | —CH₂— | —CH₂— |
| (A38) | 0 | 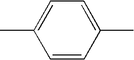 | 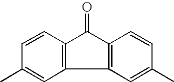 | — | —CH₂CH₂— | —CH₂CH₂— |
| (A39) | 0 | 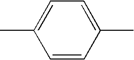 | 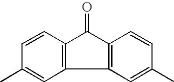 | — | —CH₂CH₂CH₂— | CH₂CH₂CH₂— |
| (A40) | 0 | 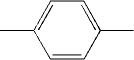 | 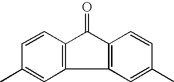 | — | 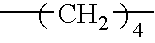 | 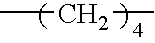 |
| (A41) | 0 | 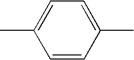 | 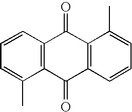 | — | —CH₂— | —CH₂— |

TABLE 30

| Compound | | | | | | |
|---|---|---|---|---|---|---|
| No. | n | Ar₁ | Ar₂ | Ar₃ | T₁ | T₂ |
| (A42) | 0 | 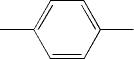 | 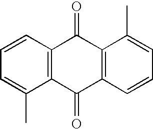 | — | —CH₂CH₂— | —CH₂CH₂— |
| (A43) | 0 | 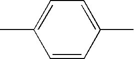 | 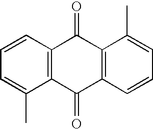 | — | —CH₂CH₂CH₂— | —CH₂CH₂CH₂— |
| (A44) | 0 | 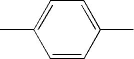 | 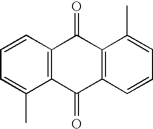 | — | 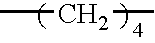 | 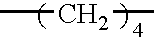 |
| (A45) | 0 | 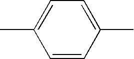 | 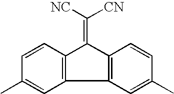 | — | —CH₂— | —CH₂— |
| (A46) | 0 | 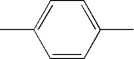 | 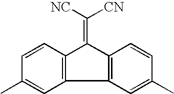 | — | —CH₂CH₂— | —CH₂CH₂— |
| (A47) | 0 | 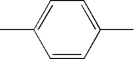 | 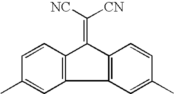 | — | —CH₂CH₂CH₂— | —CH₂CH₂CH₂— |
| (A48) | 0 | 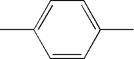 | 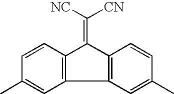 | — | 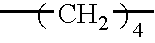 | 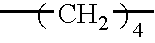 |

TABLE 31

| Compound | | | | | | |
|---|---|---|---|---|---|---|
| No. | n | Ar₁ | Ar₂ | Ar₃ | T₁ | T₂ |
| (A49) | 0 | 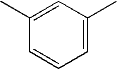 | 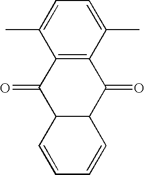 | — | —CH₂— | —CH₂— |
| (A50) | 0 | 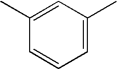 | 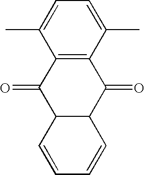 | — | —CH₂CH₂— | —CH₂CH₂— |
| (A51) | 0 | 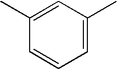 | 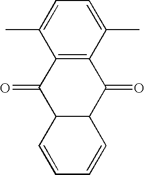 | — | —CH₂CH₂CH₂— | —CH₂CH₂CH₂— |
| (A52) | 0 | 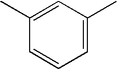 | 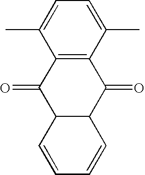 | — | 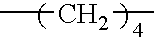 | 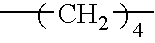 |
| (A53) | 0 | 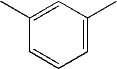 | 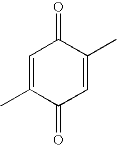 | — | —CH₂— | —CH₂— |
| (A54) | 0 | 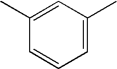 | 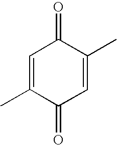 | — | —CH₂CH₂— | —CH₂CH₂— |

TABLE 32

| Compound | | | | | | |
|---|---|---|---|---|---|---|
| No. | n | Ar₁ | Ar₂ | Ar₃ | T₁ | T₂ |
| (A55) | 0 | 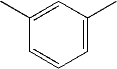 | 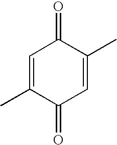 | — | —CH₂CH₂CH₂— | —CH₂CH₂CH₂— |
| (A56) | 0 | 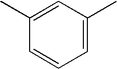 | 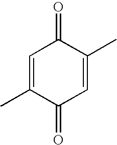 | — | 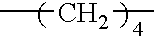 | 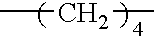 |
| (A57) | 0 | 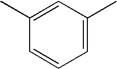 | 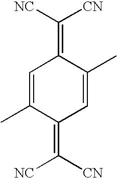 | — | —CH₂— | —CH₂— |
| (A58) | 0 | 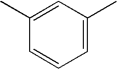 | 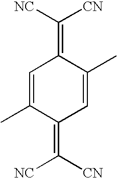 | — | —CH₂CH₂— | —CH₂CH₂— |
| (A59) | 0 | 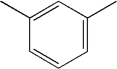 | 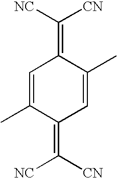 | — | —CH₂CH₂CH₂— | —CH₂CH₂CH₂— |
| (A60) | 0 | 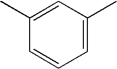 | 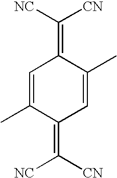 | — | 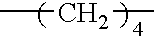 | 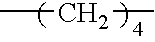 |

TABLE 33

| Compound | | | | | | |
|---|---|---|---|---|---|---|
| No. | n | Ar₁ | Ar₂ | Ar₃ | T₁ | T₂ |
| (A61) | 1 | 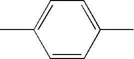 | 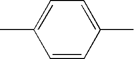 | 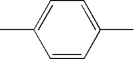 | —CH₂— | —CH₂— |
| (A62) | 1 | 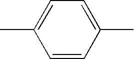 | 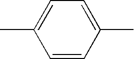 | 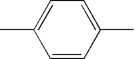 | —CH₂CH₂— | —CH₂CH₂— |
| (A63) | 1 | 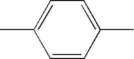 | 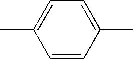 | 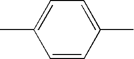 | —CH₂CH₂CH₂— | —CH₂CH₂CH₂— |
| (A64) | 1 | 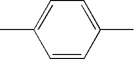 | 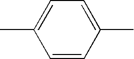 | 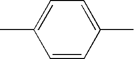 | 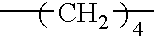 | 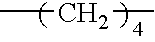 |
| (A65) | 1 | 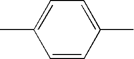 | 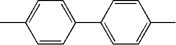 | 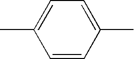 | —CH₂— | —CH₂— |
| (A66) | 1 | 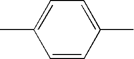 | 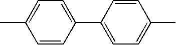 | 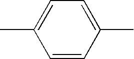 | —CH₂CH₂— | —CH₂CH₂— |
| (A67) | 1 | 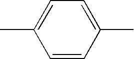 | 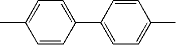 | 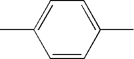 | —CH₂CH₂CH₂— | —CH₂CH₂CH₂— |
| (A68) | 1 | 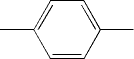 | 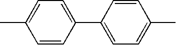 | 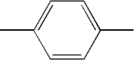 | 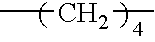 | 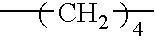 |
| (A69) | 1 | 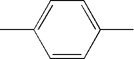 | 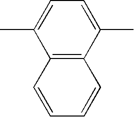 | 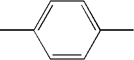 | —CH₂— | —CH₂— |

TABLE 34

| Compound | | | | | | |
|---|---|---|---|---|---|---|
| No. | n | Ar₁ | Ar₂ | Ar₃ | T₁ | T₂ |
| (A70) | 1 | 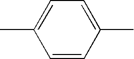 | 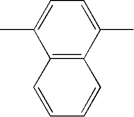 | 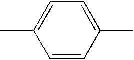 | —CH₂CH₂— | —CH₂CH₂— |
| (A71) | 1 | 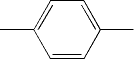 | 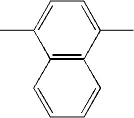 | 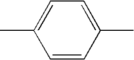 | —CH₂CH₂CH₂— | —CH₂CH₂CH₂— |
| (A72) | 1 | 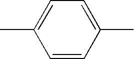 | 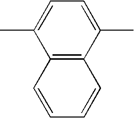 | 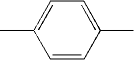 | 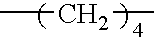 | 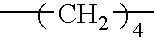 |
| (A73) | 1 | 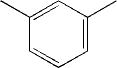 | 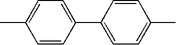 | 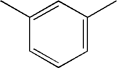 | —CH₂— | —CH₂— |
| (A74) | 1 | 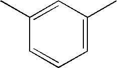 | 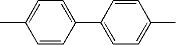 | 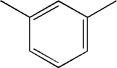 | —CH₂CH₂— | —CH₂CH₂— |
| (A75) | 1 | 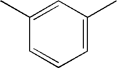 | 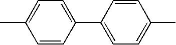 | 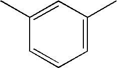 | —CH₂CH₂CH₂— | —CH₂CH₂CH₂— |
| (A76) | 1 | 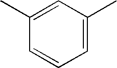 | 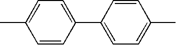 | 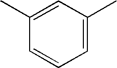 | 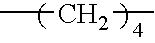 | 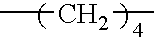 |
| (A77) | 1 | 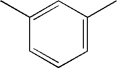 | 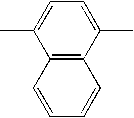 | 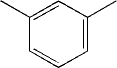 | —CH₂— | —CH₂— |

TABLE 35

| Compound | | | | | | |
|---|---|---|---|---|---|---|
| No. | n | Ar₁ | Ar₂ | Ar₃ | T₁ | T₂ |
| (A78) | 1 | 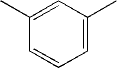 | 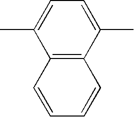 | 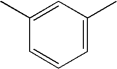 | —CH₂CH₂— | —CH₂CH₂— |
| (A79) | 1 | 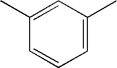 | 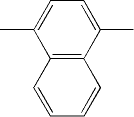 | 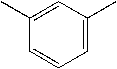 | —CH₂CH₂CH₂— | —CH₂CH₂CH₂— |
| (A80) | 1 | 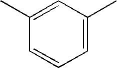 | 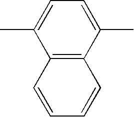 | 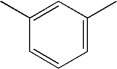 | 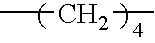 | 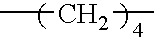 |
| (A81) | 1 | 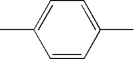 | 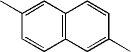 | 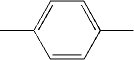 | —CH₂— | —CH₂— |
| (A82) | 1 | 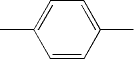 | 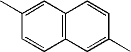 | 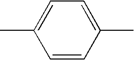 | —CH₂CH₂— | —CH₂CH₂— |
| (A83) | 1 | 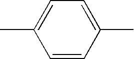 | 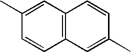 | 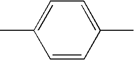 | —CH₂CH₂CH₂— | —CH₂CH₂CH₂— |
| (A84) | 1 | 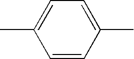 | 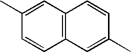 | 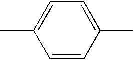 | 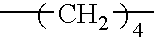 | 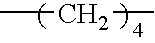 |
| (A85) | 1 | 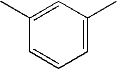 | 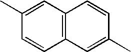 | 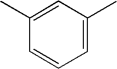 | —CH₂— | —CH₂— |

TABLE 36

| Compound | | | | | | |
|---|---|---|---|---|---|---|
| No. | n | Ar₁ | Ar₂ | Ar₃ | T₁ | T₂ |
| (A86) | 1 | 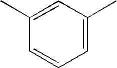 | 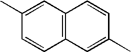 | 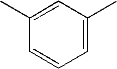 | —CH₂CH₂— | —CH₂CH₂— |
| (A87) | 1 | 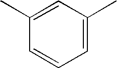 | 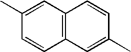 | 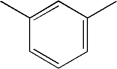 | —CH₂CH₂CH₂— | —CH₂CH₂CH₂— |
| (A88) | 1 | 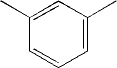 | 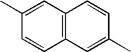 | 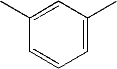 | 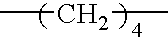 | 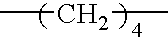 |
| (A89) | 1 | 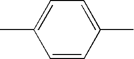 | 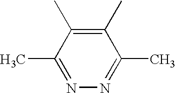 | 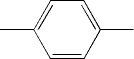 | —CH₂— | —CH₂— |
| (A90) | 1 | 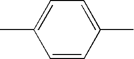 | 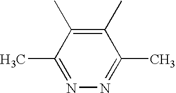 | 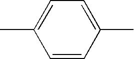 | —CH₂CH₂— | —CH₂CH₂— |
| (A91) | 1 | 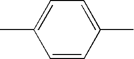 | 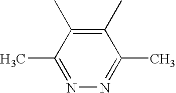 | 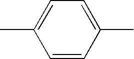 | —CH₂CH₂CH₂— | —CH₂CH₂CH₂— |
| (A92) | 1 | 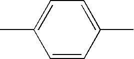 | 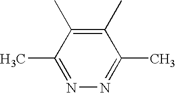 | 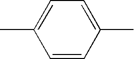 | 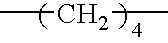 | 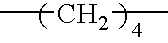 |
| (A93) | 1 | 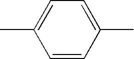 | 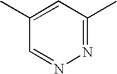 | 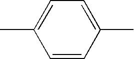 | —CH₂— | —CH₂— |

TABLE 37

| Compound | | | | | | |
|---|---|---|---|---|---|---|
| No. | n | Ar₁ | Ar₂ | Ar₃ | T₁ | T₂ |
| (A94) | 1 | 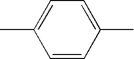 | 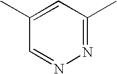 | 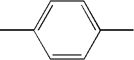 | —CH₂CH₂— | —CH₂CH₂— |
| (A95) | 1 | 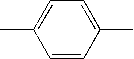 | 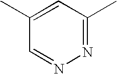 | 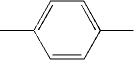 | —CH₂CH₂CH₂— | —CH₂CH₂CH₂— |
| (A96) | 1 | 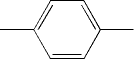 | 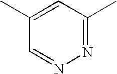 | 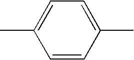 | 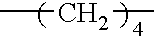 | 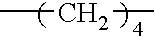 |
| (A97) | 1 | 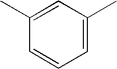 | 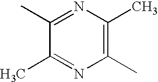 | 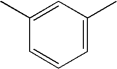 | —CH₂— | —CH₂— |
| (A98) | 1 | 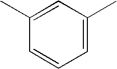 | 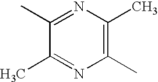 | 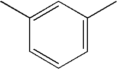 | —CH₂CH₂— | —CH₂CH₂— |
| (A99) | 1 | 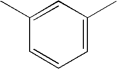 | 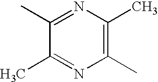 | 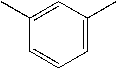 | —CH₂CH₂CH₂— | —CH₂CH₂CH₂— |
| (A100) | 1 | 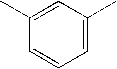 | 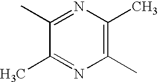 | 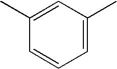 | 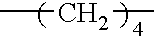 | 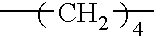 |

TABLE 38

| Compound | | | | | | |
|---|---|---|---|---|---|---|
| No. | n | Ar₁ | Ar₂ | Ar₃ | T₁ | T₂ |
| (A101) | 1 | 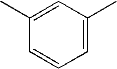 | 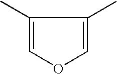 | 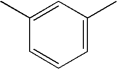 | —CH₂— | —CH₂— |
| (A102) | 1 | 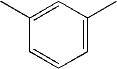 | 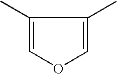 | 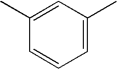 | —CH₂CH₂— | —CH₂CH₂— |
| (A103) | 1 | 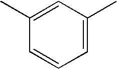 | 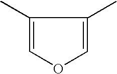 | 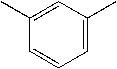 | —CH₂CH₂CH₂— | —CH₂CH₂CH₂— |
| (A104) | 1 | 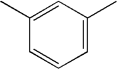 | 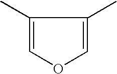 | 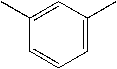 | 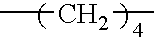 | 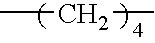 |
| (A105) | 1 | 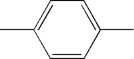 | 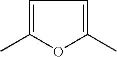 | 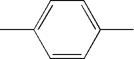 | —CH₂— | —CH₂— |
| (A106) | 1 | 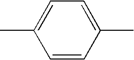 | 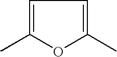 | 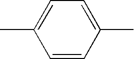 | —CH₂CH₂— | —CH₂CH₂— |
| (A107) | 1 | 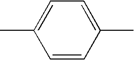 | 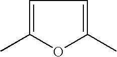 | 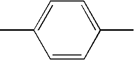 | —CH₂CH₂CH₂— | —CH₂CH₂CH₂— |

TABLE 39

| Compound | | | | | | |
|---|---|---|---|---|---|---|
| No. | n | Ar₁ | Ar₂ | Ar₃ | T₁ | T₂ |
| (A108) | 1 | 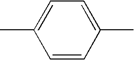 | 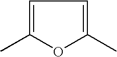 | 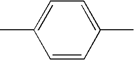 | 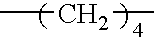 | 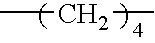 |
| (A109) | 1 | 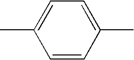 | 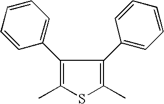 | 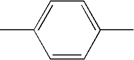 | —CH₂— | —CH₂— |
| (A110) | 1 | 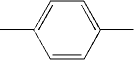 | 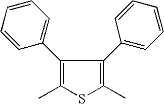 | 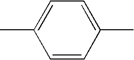 | —CH₂CH₂— | —CH₂CH₂— |
| (A111) | 1 | 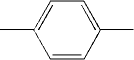 | 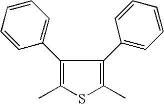 | 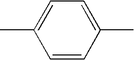 | —CH₂CH₂CH₂— | —CH₂CH₂CH₂— |
| (A112) | 1 | 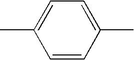 | 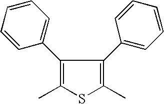 | 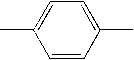 | 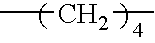 | 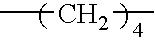 |

TABLE 40

| Compound | | | | | | |
|---|---|---|---|---|---|---|
| No. | n | Ar₁ | Ar₂ | Ar₃ | T₁ | T₂ |
| (A113) | 1 | 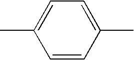 | 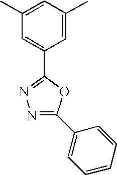 | 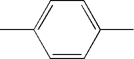 | —CH₂— | —CH₂— |
| (A114) | 1 | 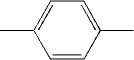 | 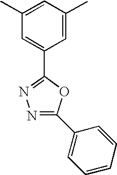 | 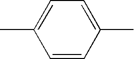 | —CH₂CH₂— | —CH₂CH₂— |
| (A115) | 1 | 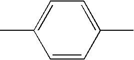 | 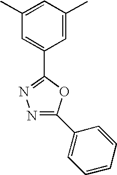 | 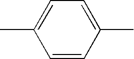 | —CH₂CH₂CH₂— | —CH₂CH₂CH₂— |
| (A116) | 1 | 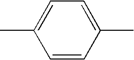 | 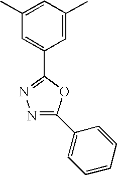 | 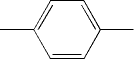 | 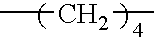 | 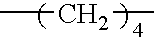 |

TABLE 41

| Compound | | | | | | |
|---|---|---|---|---|---|---|
| No. | n | Ar₁ | Ar₂ | Ar₃ | T₁ | T₂ |
| (A117) | 1 | 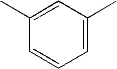 | 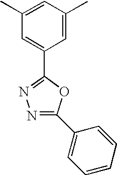 | 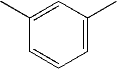 | —CH₂— | —CH₂— |
| (A118) | 1 | 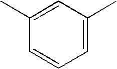 | 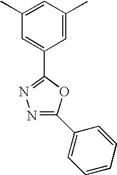 | 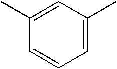 | —CH₂CH₂— | —CH₂CH₂— |
| (A119) | 1 | 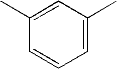 | 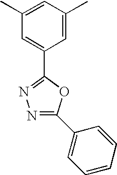 | 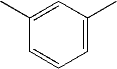 | —CH₂CH₂CH₂— | —CH₂CH₂CH₂— |

The electron transport layer of the organic electroluminescence device of the second aspect is obtained by mixing at least one hole transport material with at least one electron transport material.

The hole transport material mixed with the electron transport material of the electron transport layer of the organic electroluminescence device of the second aspect may be the same as a hole transport low molecular weight compound whose examples will be shown later or the aforementioned hole transport polymer contained in the hole transport layer.

The hole transport low molecular weight compound is, for example, a tetraphenylenediamine derivative, a triphenylamine derivative, a carbazole derivative, a stilbene derivative, an aryl hydrazine derivative, or a porphyrin compound. Typical examples thereof include, but are not limited to, the following exemplary compounds (C-1) to (C-10). One of these compounds may be used alone, or two or more of them can be used together.

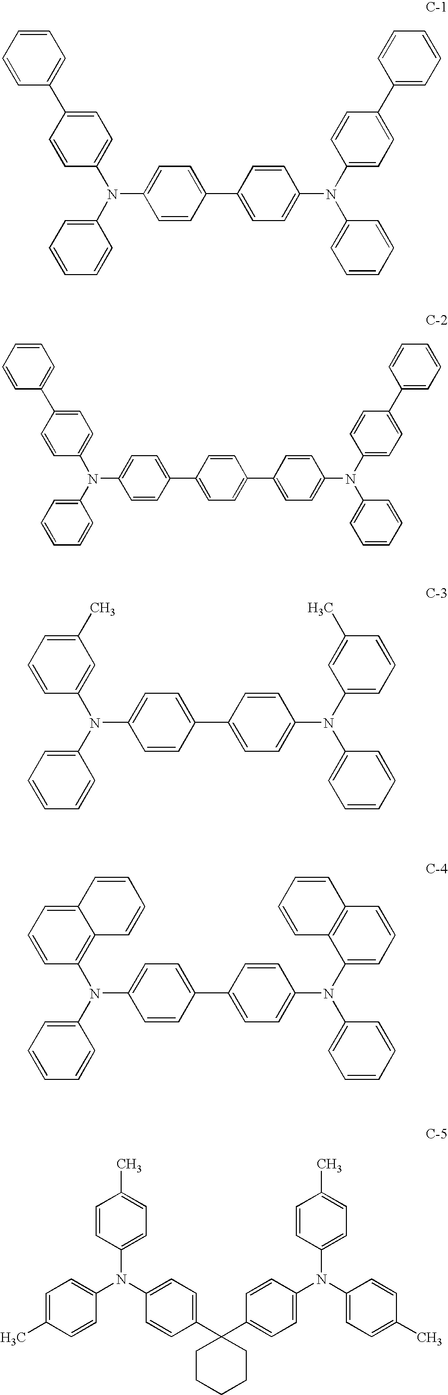

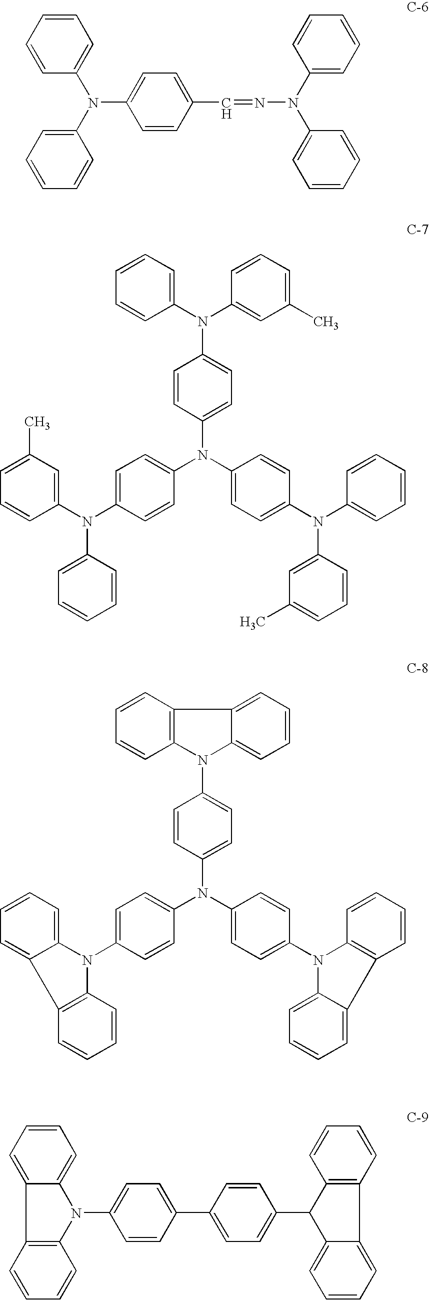

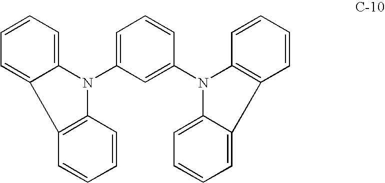

In order to ensure a sufficient electron mobility required for the electron transport layer of the organic electroluminescence device of the second aspect, the amount of the hole transport material mixed with the electron transport material is preferably in the range of about 0.01 parts by mass to about 50 parts by mass, and more preferably in the range of about 10 parts by mass to about 30 parts by mass with respect to 100 parts by mass of the electron transport material of the electron transport layer.

When the amount of the hole transport material mixed with the electron transport material of the electron transport layer is less than about 0.01 parts by mass, the electron transport layer may not obtain a hole transport ability. When the amount of the hole transport material is more than about 50 parts by mass, the electron transport layer may have a deteriorated electron transport ability.

Hereinafter, the materials of the other members and layers of the organic electroluminescence device shown in each of FIG. 1 to FIG. 3, and methods of forming the same will be explained.

An insulating substrate 18 is transparent or translucent. The insulating substrate 18 is preferably transparent since the substrate is a member out of which luminescence is taken. Accordingly, the insulating substrate 18 is made of glass or a plastic film. Like the insulating substrate 18, an electrode is transparent or translucent and is preferably transparent not to hinder taking out of luminescence. The electrode 20 preferably has a large work function in order to inject holes, and is, for example, an oxide film made of indium tin oxide (ITO), tin oxide (NESA), indium oxide, or zinc oxide, or a deposited or sputtered gold, platinum, or palladium film. Hereinafter, the insulating substrate 18 and the electrode 20 will be referred to as a transparent insulating substrate 18 and a transparent electrode 20, respectively.

A back electrode 30 is made of at least one metal that can be vacuum-deposited and that has a small work function in order to inject electrons, and the metal(s) is preferably magnesium, aluminum, silver, or indium, or an alloy thereof. A protective layer may be provided on the back electrode 30 in order to prevent moisture or oxygen from deteriorating the device. Specific examples of the material of the protective layer include metals such as In, Sn, Pb, Au, Cu, Ag, and Al; metal oxides such as MgO, SiO₂, and TiO₂; and resins such as polyethylene resin, polyurea resin, and polyimide resin. The protective layer may be formed by a vacuum deposition method, a sputtering method, a plasma polymerization method, a CVD method, or a coating method.

The organic electroluminescence device 10 shown in FIG. 1 has a transparent insulating substrate 18, a transparent electrode 20, a luminescent layer 24, an electron transport layer 26 and a back substrate 30 in that order. The organic electroluminescence device 12 shown in FIG. 2 has a transparent insulating substrate 18, a transparent electrode 20, a hole transport layer 22, a luminescent layer 24, an electron transport layer and a back substrate 30 in that order. The organic electroluminescence device 14 shown in FIG. 3 has a transparent insulating substrate 18, a transparent electrode 20, a hole transport layer 22, a luminescent layer 24, and a back substrate 30 in that order. Each of the hole transport layer 22 and the luminescent layer 24 is formed by dissolving or dispersing desired materials in an organic solvent, and applying the resultant coating solution or dispersion liquid to the transparent electrode 20 or the hole transport layer 22 by, for example, a spin coating method or a dip method.

The thickness of each of the hole transport layer 22, the luminescent layer 24, and the electron transport layer 26 is preferably about 0.1 μm or less, and more preferably in the range of about 0.03 μm to about 0.08 μm.

The materials contained in each of those layers may be either in a molecule-dispersed state or in a fine particle-dispersed state. To achieve the molecule-dispersed state of the materials in the case of a film forming method where a coating liquid is used, it is necessary that the dispersion solvent of the coating liquid be a common solvent for the materials of each of those layers. To achieve the fine particle-dispersed state of the materials, it is necessary that the dispersion solvent of the coating liquid be selected in consideration of the dispersing and dissolving properties of each of the materials. To disperse the materials into fine particles, a known apparatus such as a ball mill, a sand mill, a paint shaker, an attritor, a homogenizer, or an ultrasonic wave generator may be used.

Finally, the back electrode 30 is formed on the electron transport layer 26 or the luminescent layer 24 by a vacuum deposition method. Thus, the organic electroluminescence device is completed.

The organic electroluminescence device of the invention can emit light by applying a direct-current voltage of 1 V to 20 V between the pair of electrodes at a current density of 1 mA/cm² to 500 mA/cm².

In the following, the present invention will be further explained with examples, but the invention is not limited to the examples.

### EXAMPLES

Examples of the invention are described.

### Example 1

One part by mass of a hole transport polyester (exemplary compound CTP-1 of formula 30) as a hole transport polymer, and 0.3 parts by mass of an electron transport material (compound of formula VIII-1) are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, a compound of formula VI-1 that has been sublimated and refined is introduced as a luminescent material into a tungsten boat, and vacuum-deposited there to form a luminescent layer having a thickness of 0.05 μm on the hole transport layer.

The degree of vacuum at this time is 10⁻⁴ Pa. Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 2

One part by mass of a hole transport polyester (exemplary compound CTP-1 of formula 30) as a hole transport polymer, and 0.3 parts by mass of an electron transport material (compound of formula 31) are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 3

One part by mass of a hole transport polyester (exemplary compound CTP-1 of formula 30) as a hole transport polymer, and 0.3 parts by mass of an electron transport material (compound of formula VIII-1) are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, a compound of formula VI-1 that has been sublimated and refined is introduced as a luminescent material into a tungsten boat, and vacuum-deposited there to form a luminescent layer having a thickness of 0.05 μm on the hole transport layer.

The degree of vacuum at this time is 10 Pa. Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 4

One part by mass of a hole transport polyester (exemplary compound CTP-1 of formula 30) as a hole transport polymer, and 0.3 parts by mass of an electron transport material (compound of formula 31) are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 5

One part by mass of a hole transport polyester (exemplary compound CTP-1 of formula 30) as a hole transport polymer, and 0.3 parts by mass of a luminescent polymer (compound of formula 32) as an electron transport material are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 6

One part by mass of a hole transport polyester (exemplary compound CTP-1 of formula 30) as a hole transport polymer, and 0.3 parts by mass of a luminescent polymer (compound of formula 34) as an electron transport material are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 34 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 7

One part by mass of a hole transport polyester (exemplary compound CTP-1 of formula 30) as a hole transport polymer, and 0.3 parts by mass of a luminescent polymer (compound of formula 32) as an electron transport material are mixed, and the mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

An electron transport material of formula VIII-1 that has been sublimated and refined is introduced as an electron transport material in a tungsten boat, and vacuum-deposited there to form an electron transport layer having a thickness of 0.05 μm on the luminescent layer.

The degree of vacuum at this time is 10⁻⁴ Pa. Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 8

A device is manufactured in the same manner as in Example 1, except that a hole transport polymer is a hole transport polyester (exemplary compound CTP-7 of formula 33) rather than the hole transport polyester (exemplary compound CTP-1 of formula 30).

### Example 9

A device is manufactured in the same manner as in Example 2, except that a hole transport polyester (exemplary compound CTP-7 of formula 33), instead of the hole transport polyester (exemplary compound CTP-1 of formula 30), is used as a hole transport polymer.

### Example 10

A device is manufactured in the same manner as in Example 3, except that a hole transport polyester (exemplary compound CTP-7 of formula 33), instead of the hole transport polyester (exemplary compound CTP-1 of formula 30), is used as a hole transport polymer.

### Example 11

A device is manufactured in the same manner as in Example 4, except that a hole transport polyester (exemplary compound CTP-7 of formula 33), instead of the hole transport polyester (exemplary compound CTP-1 of formula 30), is used as a hole transport polymer.

### Example 12

A device is manufactured in the same manner as in Example 5, except that a hole transport polyester (exemplary compound CTP-7 of formula 33), instead of the hole transport polyester (exemplary compound CTP-1 of formula 30), is used as a hole transport polymer.

### Example 13

A device is manufactured in the same manner as in Example 6, except that a hole transport polyester (exemplary compound CTP-7 of formula 33), instead of the hole transport polyester (exemplary compound CTP-1 of formula 30), is used as a hole transport polymer.

### Example 14

A device is manufactured in the same manner as in Example 7, except that a hole transport polyester (exemplary compound CTP-7 of formula 33), instead of the hole transport polyester (exemplary compound CTP-1 of formula 30), is used as a hole transport polymer.

### Example 15

A device is manufactured in the same manner as in Example 5, except that a hole transport polyester (exemplary compound CTP-108 of formula 35), instead of the hole transport polyester (exemplary compound CTP-1 of formula 30), is used as a hole transport polymer.

### Example 16

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-4 shown in Table 1) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 17

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-47 shown in Table 6) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 18

One part by mass of a hole transport polyester (exemplary compound CTP-7 of formula 33) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-4 shown in Table 1) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 19

One part by mass of a hole transport polyester (exemplary compound CTP-7 of formula 33) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-47 shown in Table 6) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 20

One part by mass of a hole transport polyester (exemplary compound CTP-1 of formula 30) as a hole transport polymer, and 0.3 parts by mass of a luminescent polymer (compound 30 of formula (32)) as an electron transport layer are mixed, and the resultant mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-4 shown in Table 1) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 21

One part by mass of a hole transport polyester (exemplary compound CTP-7 of formula 33) as a hole transport polymer, and 0.3 parts by mass of a luminescent polymer (compound 30 of formula (32)) as an electron transport layer are mixed, and the resultant mixture is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport polymer (hole transport polymer having a partial structure 1-4 shown in Table 1) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 22

One part by mass of a hole transport polyester (exemplary compound CTP-7 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport low molecular weight compound (exemplary compound (C-1) of formula 36) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 23

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport low molecular weight compound (exemplary compound (C-2) of formula 37) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 24

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport low molecular weight compound (exemplary compound (C-4)) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 25

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport low molecular weight compound (exemplary compound (C-9)) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Example 26

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer, and 0.3 parts by mass of a hole transport low molecular weight compound (exemplary compound (C-10)) are mixed, and the resultant mixture is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Comparative Example 1

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, a compound of formula VI-1 that has been sublimated and refined is introduced as a luminescent material into a tungsten boat, and vacuum-deposited there to form a luminescent layer having a thickness of 0.05 μm on the hole transport layer.

The degree of vacuum at this time is 10⁻⁴ Pa. Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

### Comparative Example 2

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

Finally, copper (Ca) is deposited on the luminescent layer, and aluminum is then deposited on the resultant copper layer to form back electrodes that have a width of 2 mm and a thickness of 0.15 μm and that intersect with the ITO electrodes in the plan view. The effective surface area of the formed organic EL device is 0.04 cm².

### Comparative Example 3

One part by mass of a hole transport polyester (exemplary compound CTP-1 of formula 30) as a hole transport polymer is dissolved in monochlorobenzene to prepare a monochlorobenzene solution having a concentration of 1 mass %, which is filtered with a polytetrafluoroethylene (PTFE) filter having a pore size of 0.1 μm. A glass substrate on which rectangular ITO electrodes having a width of 2 mm are formed by etching is cleaned, and the above solution is then applied to the electrode-formed surface of the glass substrate by a spin coating method to form a hole transport layer having a thickness of 0.04 μm.

After the glass substrate is sufficiently dried, one part by mass of compound of formula 32 as a luminescent polymer is dissolved in xylene to prepare a xylene solution having a concentration of 1 mass %, and the xylene solution is filtered with a PTFE filter having a pore size of 0.1 μm. This solution is applied to the hole transport layer by a spin coating method to form a luminescent layer having a thickness of 0.06 μm.

An electron transport material (compound of formula VIII-1) is put in a tungsten boat, and vacuum-deposited to form an electron transport layer having a thickness of 0.05 μm on the luminescent layer.

The degree of vacuum at this time is 10⁻⁴ Pa. Subsequently, an Mg—Ag alloy is co-deposited on the luminescent layer to form back electrodes that have a width of 2 mm and a thickness of 0.15 μm and that intersect with the ITO electrodes in the plan view. The effective surface area of the formed organic EL device is 0.04 cm².

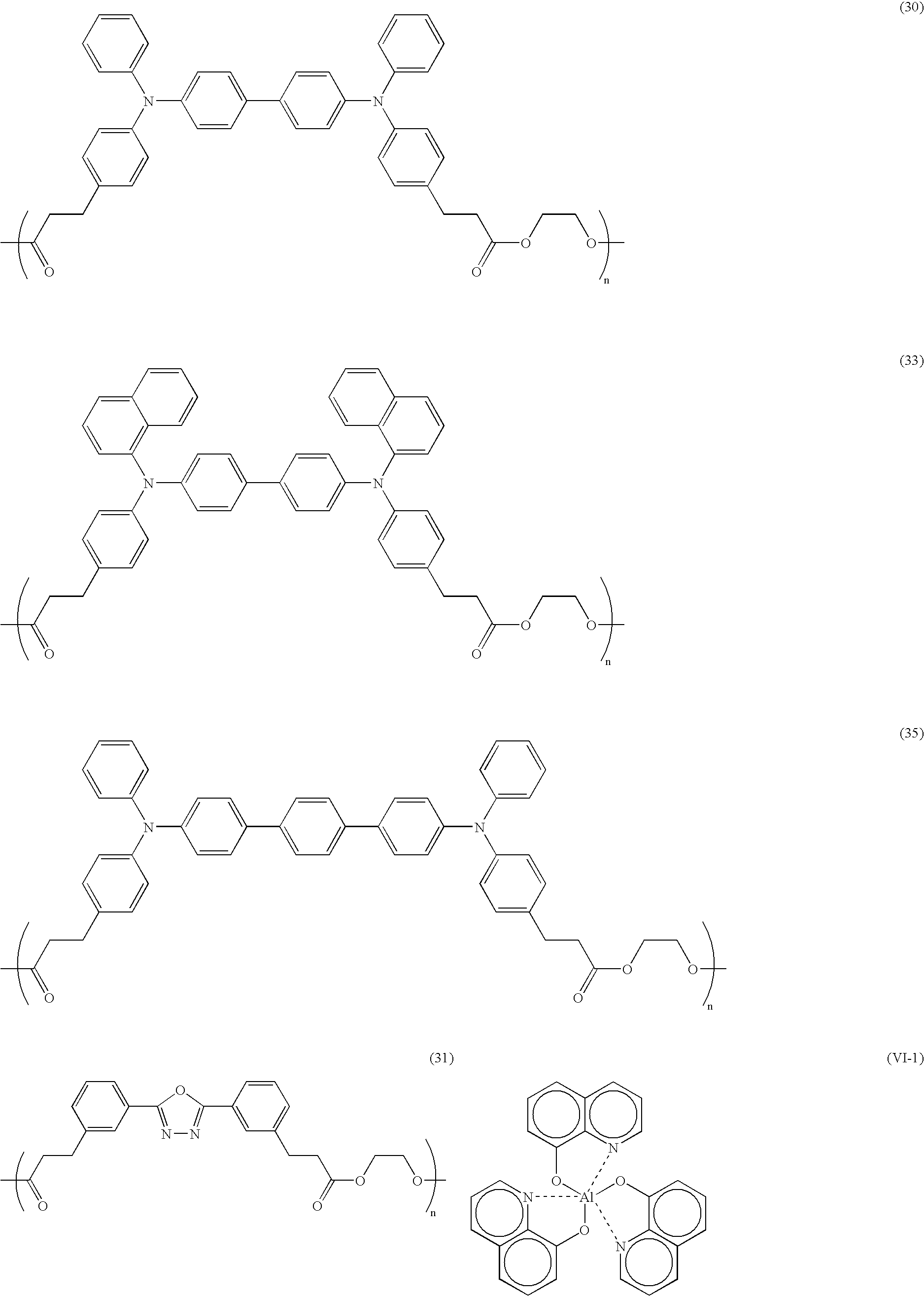

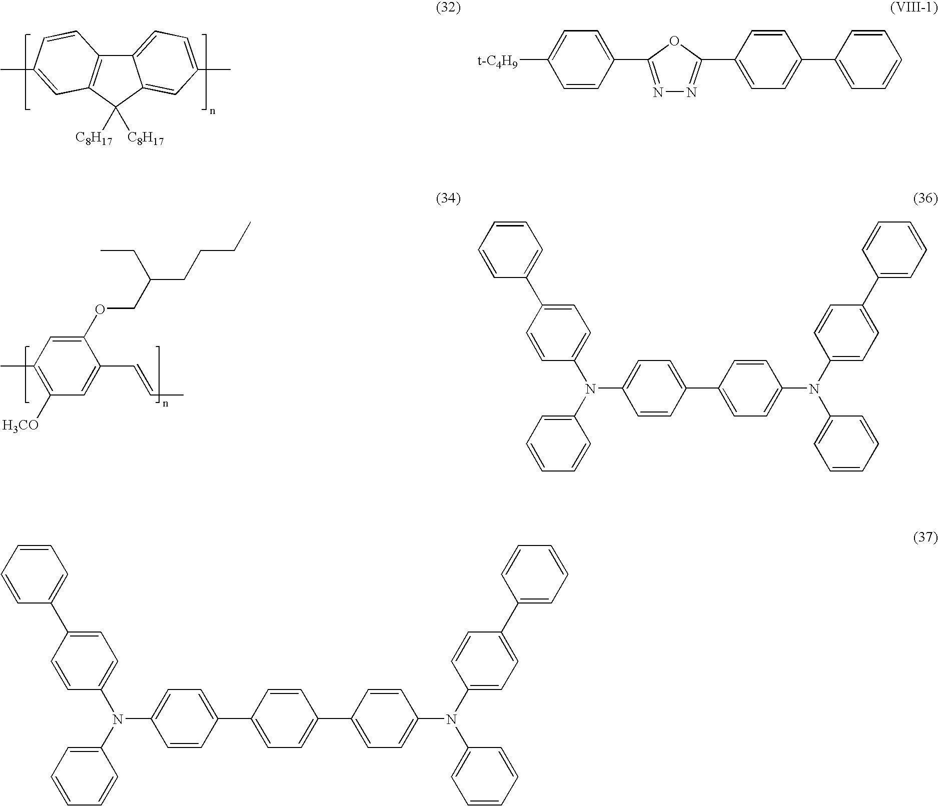

### Evaluation

A direct-current voltage of 7 V is applied to each of the organic electroluminescence devices of Examples 1-26 and Comparative Examples 1-3 in vacuum (1.3×10⁻⁵ Pa (i.e., 10⁻³ Torr)) so that the ITO electrode is made positive and so that the Mg—Ag back electrode is made negative. As a result, each of the organic electroluminescence devices emits light, and the maximum luminance of the light is measured.

In addition, the luminescent life of each of the organic EL devices in dry nitrogen is measured. To measure the luminescent life, the values of currents respectively applied to the devices are so set as to obtain an initial luminance of 100 cd/m². Each device is driven at a constant current, which is the corresponding one of the set currents, and the time (hour) that it takes for the luminance to reduce from the initial luminance to the half of the initial luminance at this time is measured and regarded as the device life.

Results are shown in Table 42.

TABLE 42

| | Maximum | Luminescent |
|---|---|---|
| | luminance | life |
| | (cd/m²) | (hour) |
| Example 1 | 1200 | 30 |
| Example 2 | 1300 | 32 |
| Example 3 | 1300 | 35 |
| Example 4 | 1450 | 32 |
| Example 5 | 1520 | 37 |
| Example 6 | 1500 | 38 |
| Example 7 | 1640 | 40 |
| Example 8 | 1300 | 34 |
| Example 9 | 1350 | 36 |
| Example 10 | 1420 | 38 |
| Example 11 | 1500 | 35 |
| Example 12 | 1600 | 39 |
| Example 13 | 1620 | 40 |
| Example 14 | 1700 | 42 |
| Example 15 | 1650 | 38 |
| Example 16 | 1500 | 30 |
| Example 17 | 1510 | 32 |
| Example 18 | 1550 | 35 |
| Example 19 | 1580 | 36 |
| Example 20 | 1600 | 42 |
| Example 21 | 1650 | 43 |
| Example 22 | 1800 | 50 |
| Example 23 | 1700 | 45 |
| Example 24 | 1680 | 49 |
| Example 25 | 1800 | 58 |
| Example 26 | 1850 | 60 |
| Comparative Example 1 | 1200 | 10 |
| Comparative Example 2 | 1050 | 12 |
| Comparative Example 3 | 1010 | 11 |

As shown in Examples 1 to 26 in Table 42, the organic electroluminescence device of an aspect of the invention has a higher maximum luminance but longer luminescent life than each of the organic electroluminescence devices of Comparative Examples 1 and 2 having a hole transport layer that does not include an electron transport material and that of Comparative Example 3 having a hole transport layer that does not include an electron transport material and an electron transport layer that does not include a hole transport material.

What is claimed is:

1. An organic electroluminescence device comprising a pair of electrodes at least one of which is transparent or translucent and a plurality of organic compound layers positioned between the pair of electrodes, at least one of the plurality of organic compound layers being a hole transport layer in which an electron transport material is mixed with at least one hole transport polymer, and at least one of the plurality of organic compound layers containing a luminescent material.

2. An organic electroluminescence device comprising a pair of electrodes at least one of which is transparent or translucent and a plurality of organic compound layers positioned between the pair of electrodes, at least one of the plurality of organic compound layers being an electron transport layer in which a hole transport material is mixed with at least one electron transport material, and at least one of the plurality of organic compound layers containing a luminescent material.

3. The organic electroluminescence device of claim 2, wherein the hole transport material is a hole transport low molecular weight compound.

4. The organic electroluminescence device of claim 2, wherein the hole transport material is a hole transport polymer.

5. The organic electroluminescence device of claim 1, wherein the electron transport material is the luminescent material.

6. The organic electroluminescence device of claim 1, wherein the luminescent material is a luminescent polymer.

7. The organic electroluminescence device of claim 1, wherein the electron transport material is an electron transport polymer.

8. The organic electroluminescence device of claim 1, wherein the hole transport polymer is a polymer containing at least one of structures represented by the following formulas (I-1) and (I-2) as a partial structure of a repeating unit: 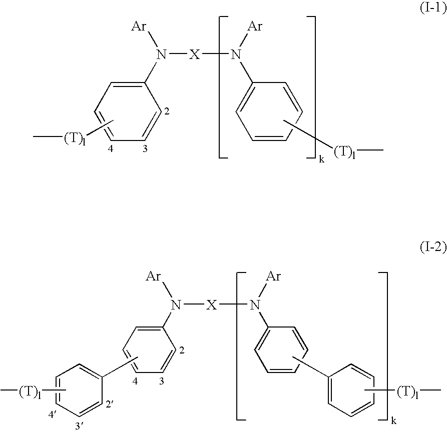
wherein, in the formulas (I-1) and (I-2), Ar is a monovalent polynuclear aromatic ring having 1 to 10 substituted or unsubstituted aromatic rings, or a monovalent condensed aromatic ring having 2 to 10 substituted or unsubstituted aromatic rings; X is a substituted or unsubstituted divalent aromatic group; k and l each represent either 0 or 1; and T is a linear divalent hydrocarbon group having 1 to 10 carbon atoms, or a branched divalent hydrocarbon group having 1 to 10 carbon atoms.

9. The organic electroluminescence device of claim 8, wherein the hole transport polymer is a polymer containing at least one selected from the repeating structures represented by the following formulas (II), (III), (IV) and (V): 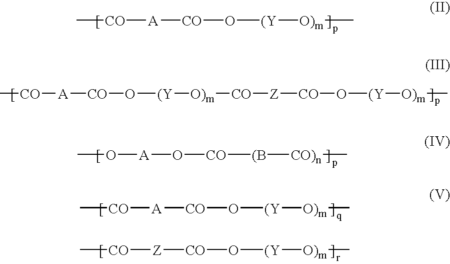
wherein, in formulas (II), (III), (IV), and (V), A is the formula (I-1) or (I-2); B is —O—(Y′—O)_{m′}—, or Z′; each of Y, Y′, Z, and Z′ is a divalent hydrocarbon group; each of m and m′ is an integer of 1 to 5; n is 0 or 1; p is an integer of 5 to 500; q is an integer of 1 to 5000; and r is an integer of 1 to 3500.

10. The organic electroluminescence device of claim 1, wherein the luminescent material is a pi-conjugate polymer.

11. The organic electroluminescence device of claim 2, wherein the electron transport material is the luminescent material.

12. The organic electroluminescence device of claim 2, wherein the luminescent material is a luminescent polymer.

13. The organic electroluminescence device of claim 2, wherein the electron transport material is an electron transport polymer.

14. The organic electroluminescence device of claim 4, wherein the hole transport polymer is a polymer containing at least one of structures represented by the following formulas (I-1) and (I-2) as a partial structure of a repeating unit: 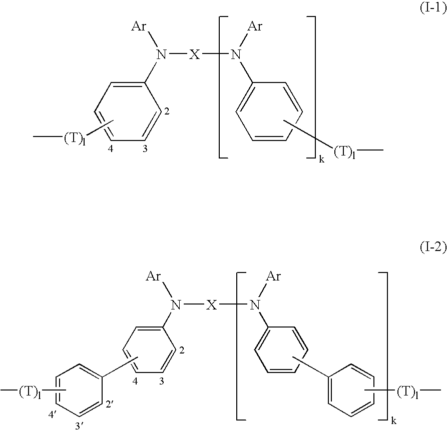
wherein, in the formulas (I-1) and (I-2), Ar is a monovalent polynuclear aromatic ring having 1 to 10 substituted or unsubstituted aromatic rings, or a monovalent condensed aromatic ring having 2 to 10 substituted or unsubstituted aromatic rings; X is a substituted or unsubstituted divalent aromatic group; k and l each represent either 0 or 1; and T is a linear divalent hydrocarbon group having 1 to 10 carbon atoms, or a branched divalent hydrocarbon group having 1 to 10 carbon atoms.

15. The organic electroluminescence device of claim 14, wherein the hole transport polymer is a polymer containing at least one selected from the repeating structures represented by the following formulas (II), (III), (IV) and (V): 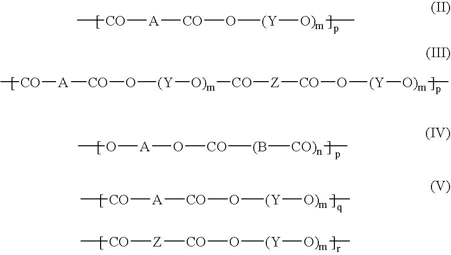
wherein, in the formulas (II), (III), (IV), and (V), A is the formula (I-1) or (I-2); B is —O—(Y′—O)_{m′}—, or Z′; each of Y, Y′, Z, and Z′ is a divalent hydrocarbon group; each of m and m′ is an integer of 1 to 5; n is 0 or 1; p is an integer of 5 to 500; q is an integer of 1 to 5000; and r is an integer of 1 to 3500.

16. The organic electroluminescence device of claim 2, wherein the luminescent material is a pi-conjugate polymer.
